(19) United States
(12) Patent Application Publication
(10) Pub. No.: US 2007/0141393 A1
(43) Pub. Date: Jun. 21, 2007

(54) Amino anthracene compounds in OLED devices

(75) Inventors: Kevin P. Klubek, West Henrietta, NY (US); Denis Y. Kondakov, Kendall, NY (US)

Correspondence Address: Paul A. Leipold;Eastman Kodak Company, Patent Legal Staff, 343 State Street, Rochester, NY, 14650-2201, US

(73) Assignee: Eastman Kodak Company

(21) Appl. No.: 11/314,548

(22) Filed: Dec. 21, 2005

(51) Int. Cl. H01L 51/54

(52) U.S. Cl. 428/690; 428/917; 313/504; 313/506; 257/E51.049; 257/E51.051

(57) ABSTRACT

An OLED device comprises a cathode, an anode, and having therebetween a light emitting layer, the device further comprising a layer on the cathode side of the emitting layer containing an anthracene compound bearing a diarylamine group; provided either (1) there is present an organic layer contiguous to the cathode that is substantially free of an anthracene compound bearing a diarylamine group, or (2) there are present independently selected diarylamine groups in both the 9- and 10-positions of the anthracene. The invention provides an improved combination of efficiency, operational lifetime, and lower operational voltage.

### FIELD OF INVENTION

This invention relates to organic electroluminescent (EL) devices containing an electron transporting layer including an amino anthracene compound.

### BACKGROUND OF THE INVENTION

While organic electroluminescent (EL) devices have been known for over two decades, their performance limitations have represented a barrier to many desirable applications. In simplest form, an organic EL device is comprised of an anode for hole injection, a cathode for electron injection, and an organic medium sandwiched between these electrodes to support charge recombination that yields emission of light. These devices are also commonly referred to as organic light-emitting diodes, or OLEDs. Representative of earlier organic EL devices are Gurnee et al. U.S. Pat. No. 3,172,862, issued Mar. 9, 1965; Gurnee U.S. Pat. No. 3,173,050, issued Mar. 9, 1965; Dresner, “Double Injection Electroluminescence in Anthracene”, RCA Review, Vol. 30, pp. 322-334, 1969; and Dresner U.S. Pat. No. 3,710,167, issued Jan. 9, 1973. The organic layers in these devices, usually composed of a polycyclic aromatic hydrocarbon, were very thick (much greater than 1 μm). Consequently, operating voltages were very high, often >100V.

More recent organic EL devices include an organic EL element consisting of extremely thin layers (e.g. <1.0 μm) between the anode and the cathode. Herein, the term “organic EL element” encompasses the layers between the anode and cathode electrodes. Reducing the thickness lowered the resistance of the organic layer and has enabled devices that operate much lower voltage. In a basic two-layer EL device structure, described first in U.S. Pat. No. 4,356,429, one organic layer of the EL element adjacent to the anode is specifically chosen to transport holes, therefore, it is referred to as the hole-transporting layer, and the other organic layer is specifically chosen to transport electrons, referred to as the electron-transporting layer. Recombination of the injected holes and electrons within the organic EL element results in efficient electroluminescence.

There have also been proposed three-layer organic EL devices that contain an organic light-emitting layer (LEL) between the hole-transporting layer and electron-transporting layer, such as that disclosed by Tang et al [J. Applied Physics, Vol. 65, Pages 3610-3616, 1989]. The light-emitting layer commonly consists of a host material doped with a guest material. Still further, there has been proposed in U.S. Pat. No. 4,769,292 a four-layer EL element comprising a hole-injecting layer (HIL), a hole-transporting layer (HTL), a light-emitting layer (LEL) and an electron transporting (ETL). These structures have resulted in improved device efficiency.

One of the most common materials used in many OLED devices is tris(8-quinolinolato)aluminum (III) (Alq). This metal complex is an excellent electron-transporting material and has been used for many years in the industry.

Aminoanthracenes have been useful in EL devices, typically used in the HTL, or the LEL such as disclosed in JP200328534.

However, it would be desirable to find new materials to replace Alq that would afford further improve device efficiency, operational lifetime, and lower operational voltage in electroluminescent devices.

### SUMMARY OF THE INVENTION

The invention provides an OLED device comprising a cathode, an anode, and having therebetween a light emitting layer, the device further comprising a layer on the cathode side of the emitting layer containing an anthracene compound bearing a diarylamine group; provided either (1) there is present an organic layer contiguous to the cathode that is substantially free of an anthracene compound bearing a diarylamine group, or (2) there are present independently selected diarylamine groups in both the 9- and 10-positions of the anthracene.

The invention provides an improved combination of efficiency, operational lifetime, and lower operational voltage.

### BRIEF DESCRIPTION OF THE DRAWINGS

FIG. 1 shows a cross-section of an OLED device of this invention.

### DETAILED DESCRIPTION OF THE INVENTION

The invention is generally described above. The invention provides in one embodiment an OLED device comprising a cathode, an anode, and having therebetween a light emitting layer, the device further comprising a layer on the cathode side of the emitting layer containing an anthracene compound bearing a diarylamine group; provided there is present an organic layer contiguous to the cathode that is substantially free of an anthracene compound bearing a diarylamine group. As used in this application, substantially free means less than 10 wt. %.

The anthracene compound in the layer adjacent to the emitting layer can be represented by Formula I: 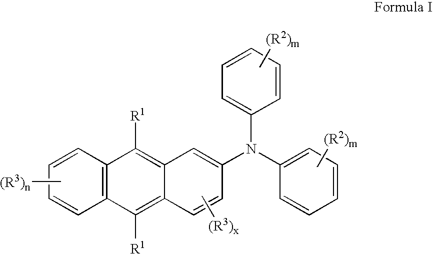
wherein each R¹ is independently selected from an aryl amine, alkyl amine, alkyl, aryl, and heteroaryl group; each R² and R³ is independently selected from alkyl, aryl, heteroaryl, fluoro, aryl amine, alkyl amine, and cyano groups, provided that the groups may join together to form fused rings; each m is an integer independently selected from 0 to 5; n is an integer independently selected from 0 to 4; and x is an integer independently selected from 0 to 3.

In a preferred embodiment of the anthracene each R¹ is selected from an alkyl, aryl, and heteroaryl group; and each R² and R³ is independently selected from alkyl, aryl and heteroaryl groups, provided that the groups may join together to form fused rings. Examples of R¹ are substituted or unsubstituted phenyl, naphthyl, and anthryl groups.

The layer contiguous with the cathode desirably comprises a compound containing at least one heteroaromatic ring. Non-limiting examples include a wide variety of materials from various classes including: phenanthrolines, benzazoles, metal chelated oxinoids, triazines, triazoles, pyridines, oxadiazoles, quinoxalines, quinolines, and their derivatives. Other materials suitable for use in the layer contiguous to the cathode may be selected from imidazoles, oxazoles, pyrimidines, pyrazines, and their derivatives.

Phenanthrolines may be represented by formula (ETF-1): 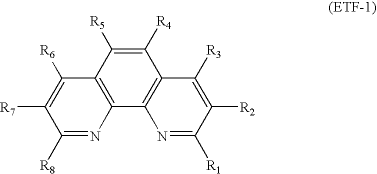
wherein; R₁-R₈ are independently hydrogen, alkyl group, aryl or substituted aryl group, and at least one of R₁-R₈ is aryl group or substituted aryl group. Examples of phenanthrolines are:

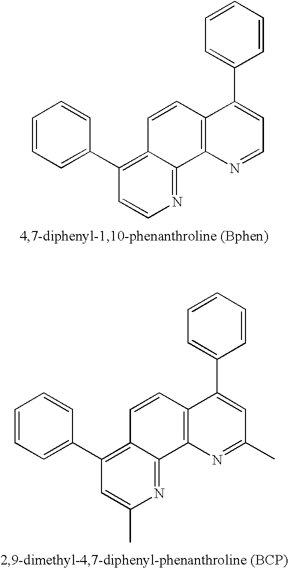

Benzazoles satisfying structural formula (ETF-2) are also useful as materials contiguous to the cathode: 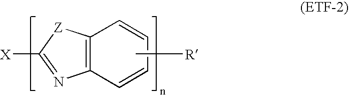
wherein n is an integer of 3 to 8; Z is O, NR or S; and R and R′ are individually hydrogen; alkyl of from 1 to 24 carbon atoms, for example, propyl, t-butyl, heptyl, and the like; aryl or hetero-atom substituted aryl of from 5 to 20 carbon atoms for example phenyl and naphthyl, furyl, thienyl, pyridyl, quinolinyl and other heterocyclic systems; or fluoro; or atoms necessary to complete a fused aromatic ring; and X is a linkage unit consisting of carbon, alkyl, aryl, substituted alkyl, or substituted aryl, which conjugately or unconjugately connects the multiple benzazoles together. An example of a useful benzazole is 2,2′,2″-(1,3,5-phenylene)tris[1-phenyl-1H-benzimidazole] (TPBI).

Metal chelated oxinoids (Formula ETF-3) constitute another class of useful materials for use in the layer contiguous to the cathode: 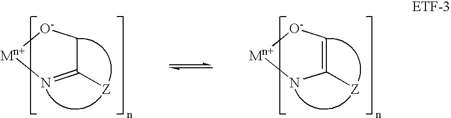
wherein; M represents a metal; n is an integer of from 1 to 4; and Z independently in each occurrence represents the atoms completing a nucleus having at least two fused aromatic rings.

From the foregoing it is apparent that the metal can be monovalent, divalent, trivalent, or tetravalent metal. The metal can, for example, be an alkali metal, such as lithium, sodium, or potassium; an alkaline earth metal, such as magnesium or calcium; an earth metal, such aluminum or gallium, or a transition metal such as zinc or zirconium. Generally any monovalent, divalent, trivalent, or tetravalent metal known to be a useful chelating metal can be employed.

Z completes a heterocyclic nucleus containing at least two fused aromatic rings, at least one of which is an azole or azine ring. Additional rings, including both aliphatic and aromatic rings, can be fused with the two required rings, if required. To avoid adding molecular bulk without improving on function the number of ring atoms is usually maintained at 18 or less.

Illustrative of useful chelated oxinoid compounds are the following:
CO-1: Aluminum trisoxine [alias, tris(8-quinolinolato)aluminum(III); Alq]
CO-2: Magnesium bisoxine [alias, bis(8-quinolinolato)magnesium(II)]
CO-3: Bis[benzo{f}-8-quinolinolato]zinc (II)
CO-4: Bis(2-methyl-8-quinolinolato)aluminum(III)-μ-oxo-bis(2-methyl-8-quinolinolato) aluminum(III)
CO-5: Indium trisoxine [alias, tris(8-quinolinolato)indium]
CO-6: Aluminum tris(5-methyloxine) [alias, tris(5-methyl-8-quinolinolato) aluminum(III)]
CO-7: Lithium oxine [alias, (8-quinolinolato)lithium(I)]
CO-8: Gallium oxine [alias, tris(8-quinolinolato)gallium(III)]
CO-9: Zirconium oxine [alias, tetra(8-quinolinolato)zirconium(IV)]

Pyridine containing materials (Figure ETF-4) constitute another class of useful materials for use in the layer contiguous to the cathode: 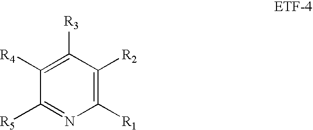
wherein; R₁-R₅ are independently hydrogen, alkyl, substituted alkyl, aryl, substituted aryl, heteroaryl, substituted heteroaryl, provided that R₁ and R₂, or R₂ and R₃, or R₃ and R₄, or R₄ and R₅ may independently join together to form fused rings.

Illustrative of useful pyridine compounds are the following:

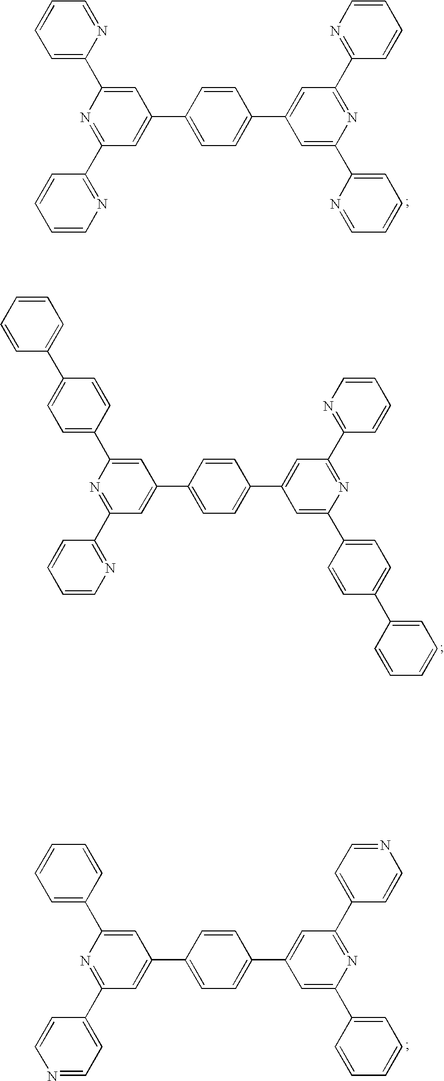

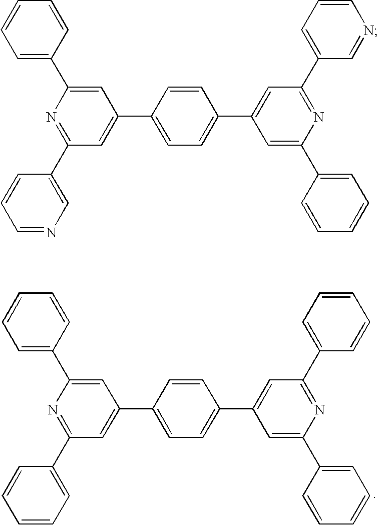

Triazine containing materials (Figure ETF-5) constitute another class of useful materials for use in the layer contiguous to the cathode: 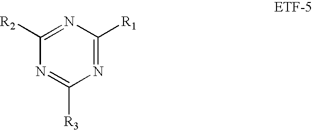
wherein R₁-R₃ are independently hydrogen, alkyl, substituted alkyl, aryl, substituted aryl, heteroaryl, or substituted heteroaryl.

Illustrative of useful triazine compounds are the following:

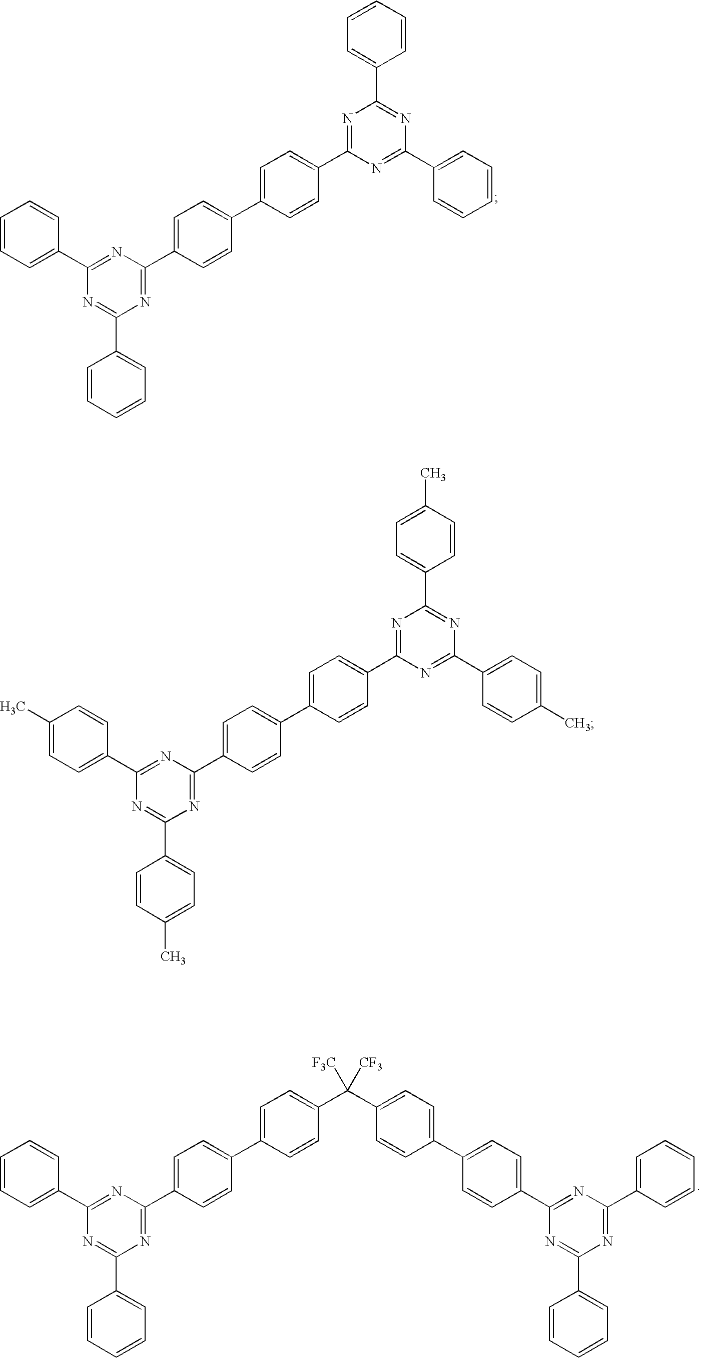

Triazole containing materials (Figure ETF-6) constitute another class of useful materials for use in the layer contiguous to the cathode: 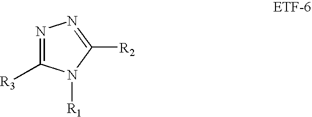
wherein; R₁-R₃ are independently hydrogen, alkyl, substituted alkyl, aryl, substituted aryl, heteroaryl, or substituted heteroaryl, wherein R₁ and R₂, or R₁ and R3 may independently join together to form fused rings.

Illustrative of useful triazole compounds are the following:

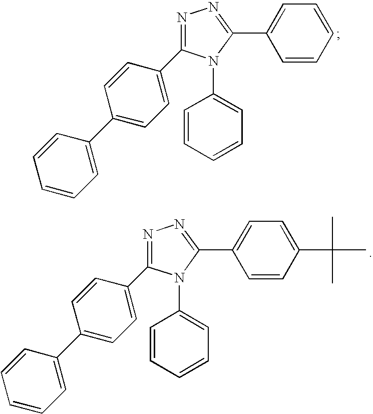

Oxadiazole containing materials (Figure ETF-7) constitute another class of useful materials for use in the layer contiguous to the cathode: 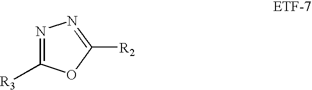
wherein; R₁-R₂ are independently hydrogen, alkyl, substituted alkyl, aryl, substituted aryl, heteroaryl, or substituted heteroaryl.

Illustrative of useful oxadiazole compounds are the following:

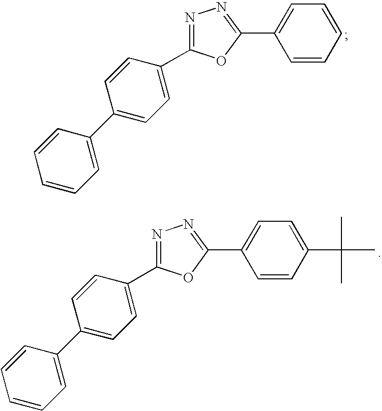

Quinoxaline containing materials (Figure ETF-8) constitute another class of useful materials for use in the layer contiguous to the cathode: 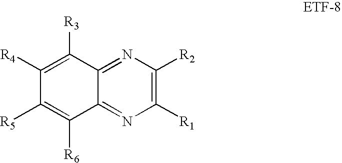
wherein; R₁-R₆ are independently hydrogen, alkyl, substituted alkyl, aryl, substituted aryl, heteroaryl, or substituted heteroaryl, provided that R₁ and R₂, or R₃ and R₄, or R₄ and R₅, or R₅ and R₆ may independently join together to form fused rings.

Illustrative of useful quinoxaline compounds are the following:

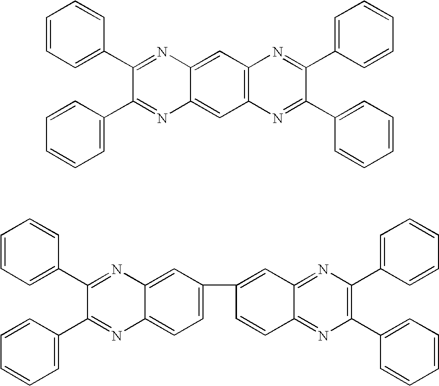

In a preferred embodiment the anthracene compound contains a diarylamine group in the 9- or 10-position and a substituent in the other of the 9- or 10-position; provided there is present an organic layer contiguous to the cathode that is substantially free of such a compound.

The anthracene compound in the layer adjacent to the emitting layer may be represented by Formula II: 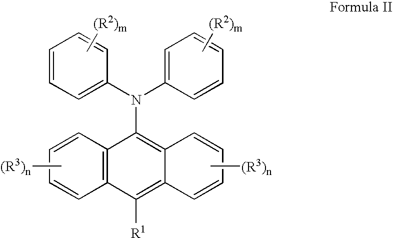
wherein; R¹ is in the 9- or 10-position and is selected from H, aryl amine, alkyl amine, alkyl, aryl, and heteroaryl group; each R² and R³ is independently selected from alkyl, aryl, heteroaryl, fluoro, aryl amine, alkyl amine, and cyano groups, provided that the groups may join together to form fused rings; each m is an integer independently selected from 0 to 5; and each n is an integer independently selected from 0 to 4.

In one example, R¹ is selected from an alkyl, aryl, and heteroaryl group; and each R² and R³ are independently selected from alkyl, aryl and heteroaryl groups, provided that the groups may join together to form fused rings. Examples of R¹ are substituted or unsubstituted phenyl, naphthyl, and anthryl groups.

In another example, R¹ is selected from substituted or unsubstituted groups shown below:

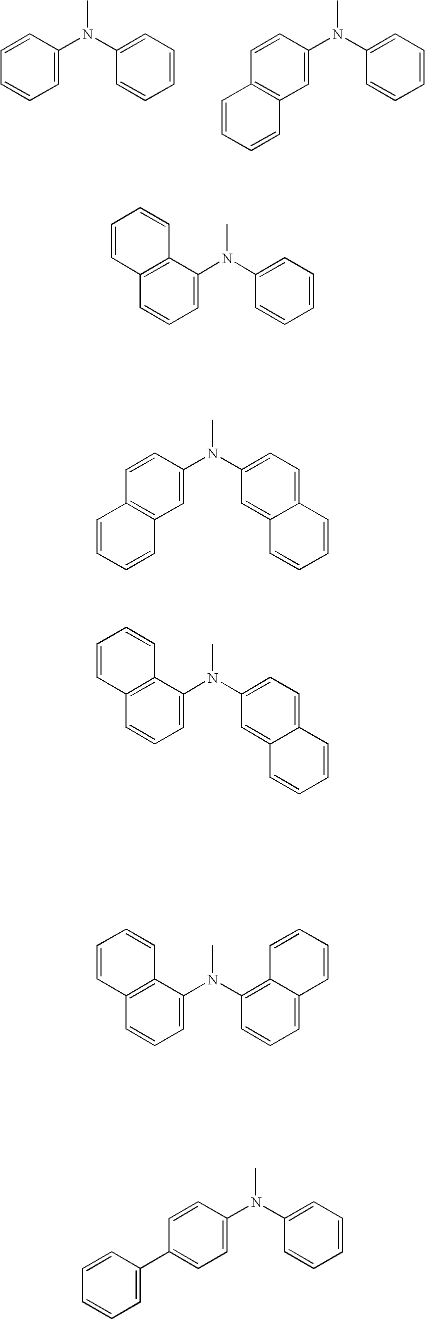

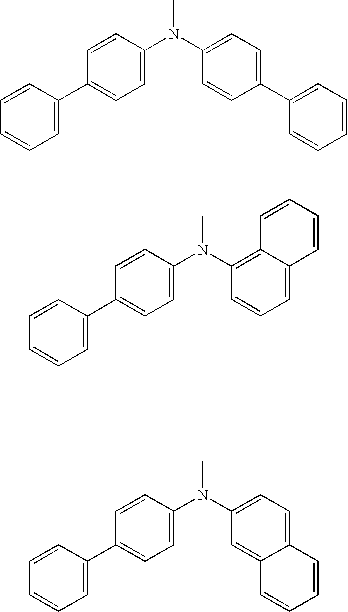

The layer contiguous to the cathode desirably comprises a compound containing at least one heteroaromatic ring. Non-limiting examples include a wide variety of materials from various classes including: phenanthrolines, benzazoles, metal chelated oxinoids, triazines, triazoles, pyridines, oxadiazoles, quinoxalines, quinolines, and their derivatives. Other materials suitable for use in the layer contiguous to the cathode may be selected from imidazoles, oxazoles, pyrimidines, pyrazines, and their derivatives. Examples were discussed previously.

In another embodiment, the invention provides an OLED device comprising a cathode, an anode, and having therebetween a light emitting layer, the device further comprising a layer on the cathode side of the emitting layer containing an anthracene compound bearing independently selected diarylamine groups in the 9- and 10-position.

The anthracene compound in the layer adjacent to the emitting layer may be represented by Formula III: 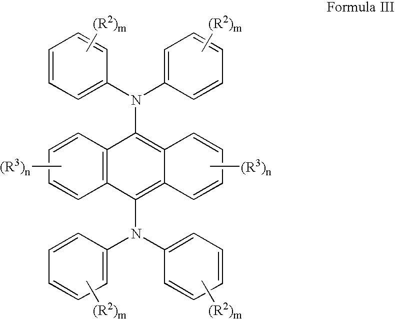
wherein each R² and R³ is independently selected from alkyl, aryl, heteroaryl, fluoro, aryl amine, alkyl amine, and cyano groups, provided that the groups may join together to form fused rings; each m is an integer independently selected from 0 to 5; and each n is an integer independently selected from 0 to 4.

In a preferred embodiment the anthracene compound represented by Formula III is a 9,10-di(naphthyl phenyl amine) anthracene.

In another preferred embodiment the anthracene compound in the layer adjacent to the emitting layer may be represented by Formula IV:

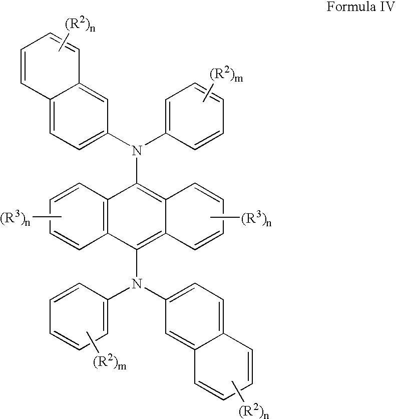

wherein each R² and R³ are independently selected from alkyl, aryl, heteroaryl, fluoro, aryl amine, alkyl amine, and cyano groups, provided that the groups may join together to form fused rings; each m is an integer independently selected from 0 to 5; and each n is an integer independently selected from 0 to 4.

Embodiments of the invention may provide advantageous features such as operating efficiency, higher luminance, color hue, low drive voltage, and improved operating stability.

Unless otherwise specifically stated, use of the term “substituted” or “substituent” means any group or atom other than hydrogen. Additionally, when the term “group” is used, it means that when a substituent group contains a substitutable hydrogen, it is also intended to encompass not only the substituent's unsubstituted form, but also its form further substituted with any substituent group or groups as herein mentioned, so long as the substituent does not destroy properties necessary for device utility. Suitably, a substituent group may be halogen or may be bonded to the remainder of the molecule by an atom of carbon, silicon, oxygen, nitrogen, phosphorous, sulfur, selenium, or boron. The substituent may be, for example: fluoro; nitro; hydroxyl; cyano; carboxyl; or groups which may be further substituted, such as alkyl, including straight or branched chain or cyclic alkyl, such as methyl, trifluoromethyl, ethyl, t-butyl, 3-(2,4-di-t-pentylphenoxy)propyl, and tetradecyl; alkenyl, such as ethylene, 2-butene; alkoxy, such as methoxy, ethoxy, propoxy, butoxy, 2-methoxyethoxy, sec-butoxy, hexyloxy, 2-ethylhexyloxy, tetradecyloxy, 2-(2,4-di-t-pentylphenoxy)ethoxy, and 2-dodecyloxyethoxy; aryl such as phenyl, 4-t-butylphenyl, 2,4,6-trimethylphenyl, naphthyl; aryloxy, such as phenoxy, 2-methylphenoxy, alpha- or beta-naphthyloxy, and 4-tolyloxy; carbonamido, such as acetamido, benzamido, butyramido, tetradecanamido, alpha-(2,4-di-t-pentyl-phenoxy)acetamido, alpha-(2,4-di-t-pentylphenoxy)butyramido, alpha-(3-pentadecylphenoxy)-hexanamido, alpha-(4-hydroxy-3-t-butylphenoxy)-tetradecanamido, 2-oxo-pyrrolidin-1-yl, 2-oxo-5-tetradecylpyrrolin-1-yl, N-methyltetradecanamido, N-succinimido, N-phthalimido, 2,5-dioxo-1-oxazolidinyl, 3-dodecyl-2,5-dioxo-1-imidazolyl, and N-acetyl-N-dodecylamino, ethoxycarbonylamino, phenoxycarbonylamino, benzyloxycarbonylamino, hexadecyloxycarbonylamino, 2,4-di-t-butylphenoxycarbonylamino, phenylcarbonylamino, 2,5-(di-t-pentylphenyl)carbonylamino, p-dodecyl-phenylcarbonylamino, p-tolyl carbonyl amino, N-methylureido, N,N-dimethylureido, N-methyl-N-dodecylureido, N-hexadecylureido, N,N-dioctadecylureido, N,N-dioctyl-N′-ethylureido, N-phenylureido, N,N-diphenylureido, N-phenyl-N-p-tolylureido, N-(m-hexadecylphenyl)ureido, N,N-(2,5-di-t-pentylphenyl)-N′-ethylureido, and t-butylcarbonamido; sulfonamido, such as methylsulfonamido, benzenesulfonamido, p-tolylsulfonamido, p-dodecylbenzenesulfonamido, N-methyltetradecylsulfonamido, N,N-dipropyl-sulfamoylamino, and hexadecylsulfonamido; sulfamoyl, such as N-methylsulfamoyl, N-ethylsulfamoyl, N,N-dipropylsulfamoyl, N-hexadecylsulfamoyl, N,N-dimethylsulfamoyl, N-[3-(dodecyloxy)propyl]sulfamoyl, N-[4-(2,4-di-t-pentylphenoxy)butyl]sulfamoyl, N-methyl-N-tetradecylsulfamoyl, and N-dodecylsulfamoyl; carbamoyl, such as N-methylcarbamoyl, N,N-dibutylcarbamoyl, N-octadecylcarbamoyl, N-[4-(2,4-di-t-pentylphenoxy)butyl]carbamoyl, N-methyl-N-tetradecylcarbamoyl, and N,N-dioctylcarbamoyl; acyl, such as acetyl, (2,4-di-t-amylphenoxy)acetyl, phenoxycarbonyl, p-dodecyloxyphenoxycarbonyl methoxycarbonyl, butoxycarbonyl, tetradecyloxycarbonyl, ethoxycarbonyl, benzyloxycarbonyl, 3-pentadecyloxycarbonyl, and dodecyloxycarbonyl; sulfonyl, such as methoxysulfonyl, octyloxysulfonyl, tetradecyloxysulfonyl, 2-ethylhexyloxysulfonyl, phenoxysulfonyl, 2,4-di-t-pentylphenoxysulfonyl, methylsulfonyl, octylsulfonyl, 2-ethylhexylsulfonyl, dodecylsulfonyl, hexadecylsulfonyl, phenylsulfonyl, 4-nonylphenylsulfonyl, and p-tolylsulfonyl; sulfonyloxy, such as dodecylsulfonyloxy, and hexadecylsulfonyloxy; sulfinyl, such as methylsulfinyl, octylsulfinyl, 2-ethylhexylsulfinyl, dodecylsulfinyl, hexadecylsulfinyl, phenylsulfinyl, 4-nonylphenylsulfinyl, and p-tolylsulfinyl; thio, such as ethylthio, octylthio, benzylthio, tetradecylthio, 2-(2,4-di-t-pentylphenoxy)ethylthio, phenylthio, 2-butoxy-5-t-octylphenylthio, and p-tolylthio; acyloxy, such as acetyloxy, benzoyloxy, octadecanoyloxy, p-dodecylamidobenzoyloxy, N-phenylcarbamoyloxy, N-ethylcarbamoyloxy, and cyclohexylcarbonyloxy; amine, such as phenylanilino, 2-chloroanilino, diethylamine, dodecylamine; imino, such as 1 (N-phenylimido)ethyl, N-succinimido or 3-benzylhydantoinyl; phosphate, such as dimethylphosphate and ethylbutylphosphate; phosphite, such as diethyl and dihexylphosphite; a heterocyclic group, a heterocyclic oxy group or a heterocyclic thio group, each of which may be substituted and which contain a 3 to 7 membered heterocyclic ring composed of carbon atoms and at least one hetero atom selected from the group consisting of oxygen, nitrogen, sulfur or phosphorous, such as pyridyl, thienyl, furyl, azolyl, thiazolyl, oxazolyl, imidazolyl, pyrazolyl, pyrazinyl, pyrimidinyl, pyrolidinonyl, quinolinyl, isoquinolinyl, 2-furyl, 2-thienyl, 2-benzimidazolyloxy or 2-benzothiazolyl; quaternary ammonium, such as triethylammonium; quaternary phosphonium, such as triphenylphosphonium; and silyloxy, such as trimethylsilyloxy.

If desired, the substituents may themselves be further substituted one or more times with the described substituent groups. The particular substituents used may be selected by those skilled in the art to attain desirable properties for a specific application and can include, for example, electron-withdrawing groups, electron-donating groups, and steric groups. When a molecule may have two or more substituents, the substituents may be joined together to form a ring such as a fused ring unless otherwise provided. Generally, the above groups and substituents thereof may include those having up to 48 carbon atoms, typically 1 to 36 carbon atoms and usually less than 24 carbon atoms, but greater numbers are possible depending on the particular substituents selected.

For the purpose of this invention, also included in the definition of a heterocyclic ring are those rings that include coordinate or dative bonds. The definition of a coordinate bond can be found in Grant & Hackh's Chemical Dictionary, page 91. In essence, a coordinate bond is formed when electron rich atoms such as O or N, donate a pair of electrons to electron deficient atoms such as Al or B.

It is well within the skill of the art to determine whether a particular group is electron donating or electron accepting. The most common measure of electron donating and accepting properties is in terms of Hammett σ values. Hydrogen has a Hammett σ value of zero, while electron donating groups have negative Hammett σ values and electron accepting groups have positive Hammett σ values. Lange's handbook of Chemistry, 12^{th} Ed., McGraw Hill, 1979, Table 3-12, pp. 3-134 to 3-138, here incorporated by reference, lists Hammett σ values for a large number of commonly encountered groups. Hammett σ values are assigned based on phenyl ring substitution, but they provide a practical guide for qualitatively selecting electron donating and accepting groups.

Suitable electron donating groups may be selected from —R′, —OR′, and —NR′(R″) where R′ is a hydrocarbon containing up to 6 carbon atoms and R″ is hydrogen or R′. Specific examples of electron donating groups include methyl, ethyl, phenyl, methoxy, ethoxy, phenoxy, —N(CH₃)₂, —N(CH₂CH₃)₂, —NHCH₃, —N(C₆H₅)₂, —N(CH₃)(C₆H₅), and —NHC₆H₅.

Suitable electron accepting groups may be selected from the group consisting of cyano, α-haloalkyl, α-haloalkoxy, amido, sulfonyl, carbonyl, carbonyloxy and oxycarbonyl substituents containing up to 10 carbon atoms. Specific examples include —CN, —F, —CF₃, —OCF₃, —CONHC₆H₅, —SO₂C₆H₅, —COC₆H₅, —CO₂C₆H₅, and —OCOC₆H₅.

Unless otherwise specified, the term “percentage” or “percent” and the symbol “%” of a material indicates the volume percent of the material in the layer in which it is present.

Useful compounds of this invention include: 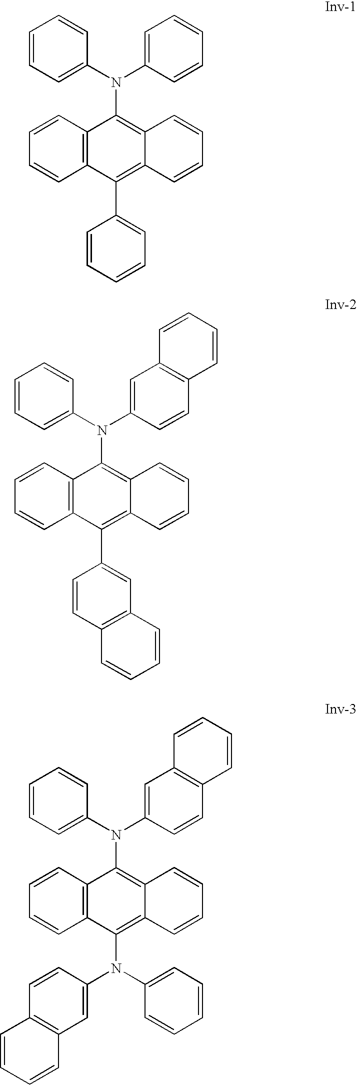 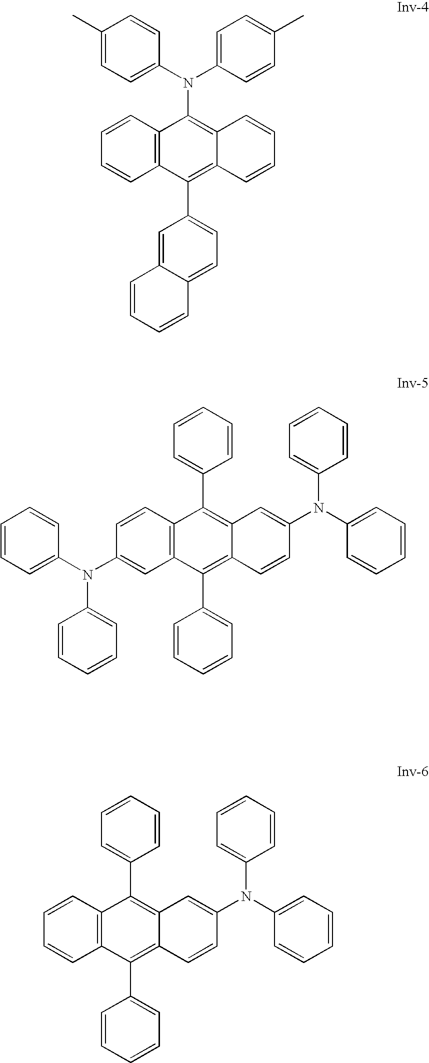 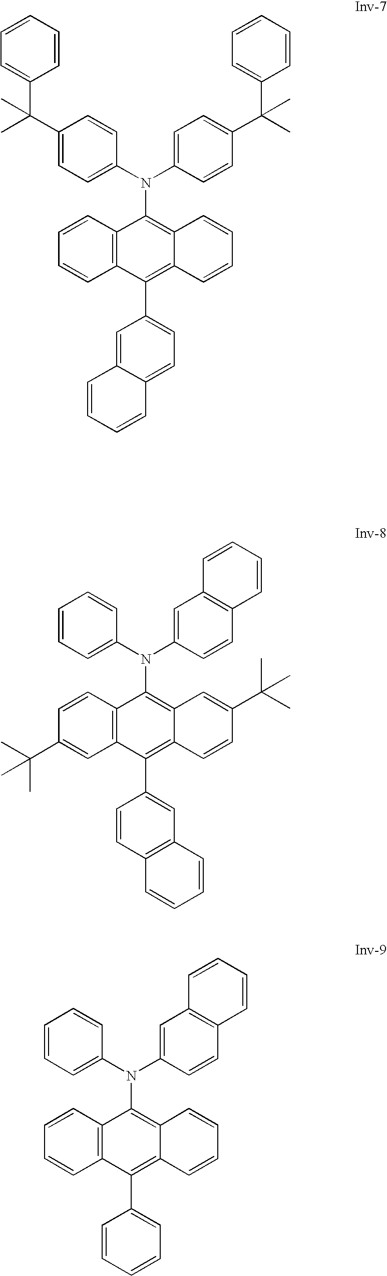 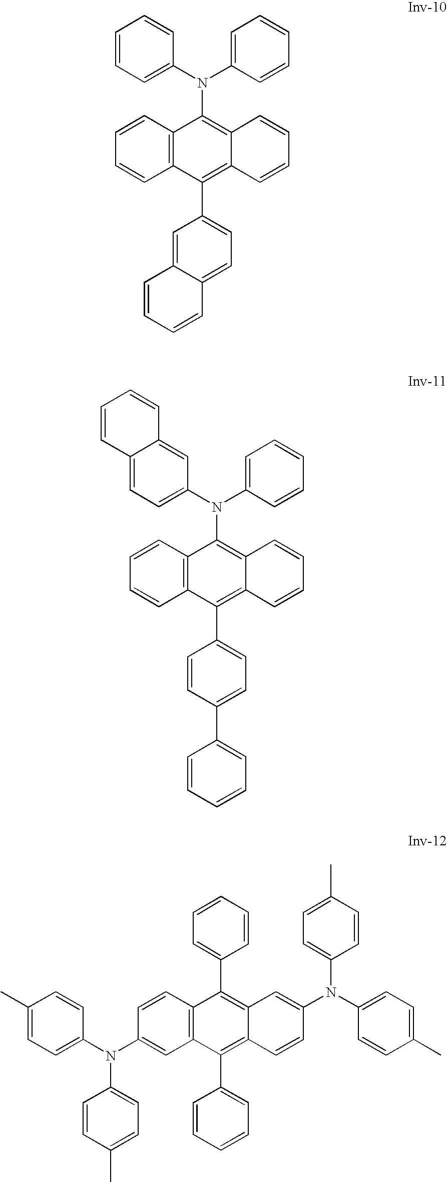 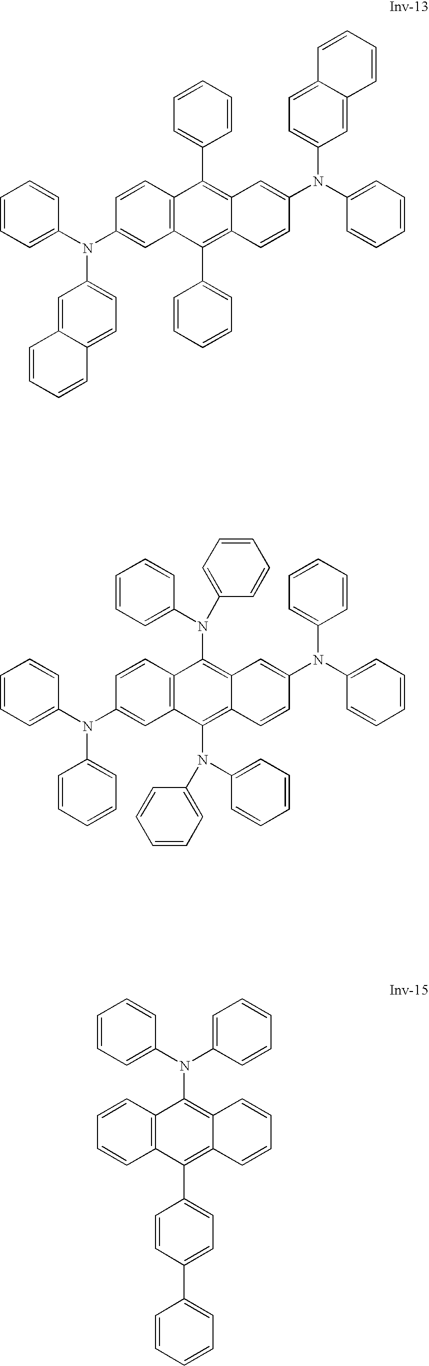 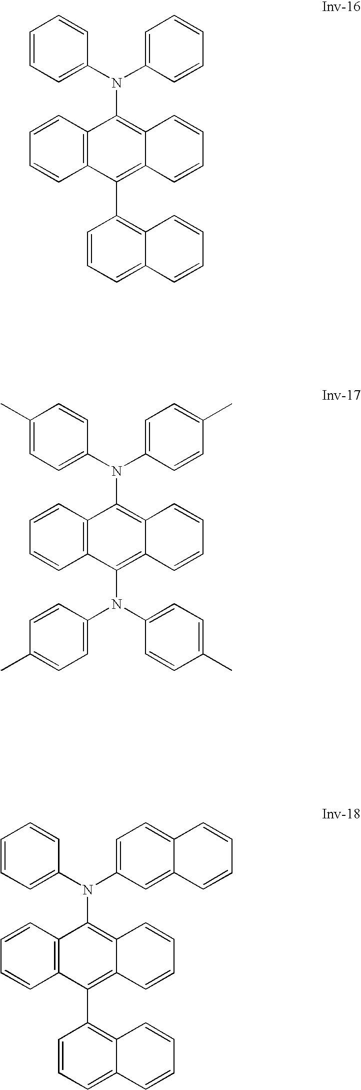 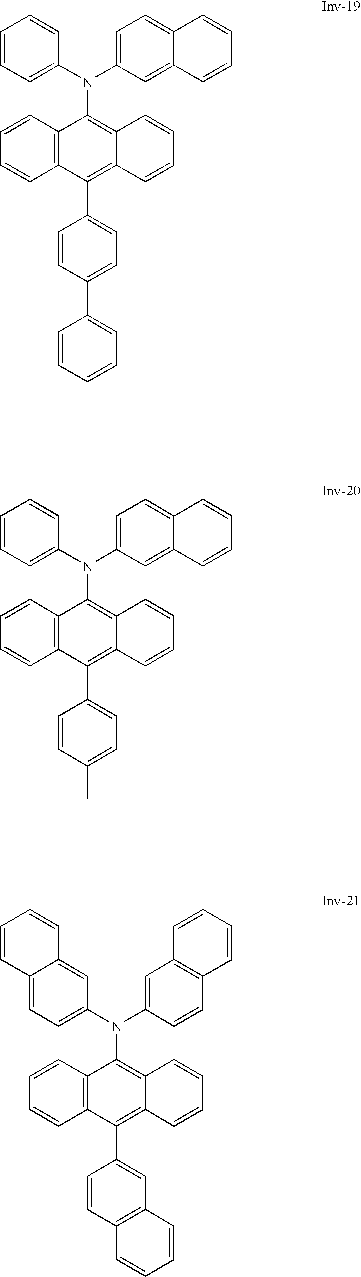 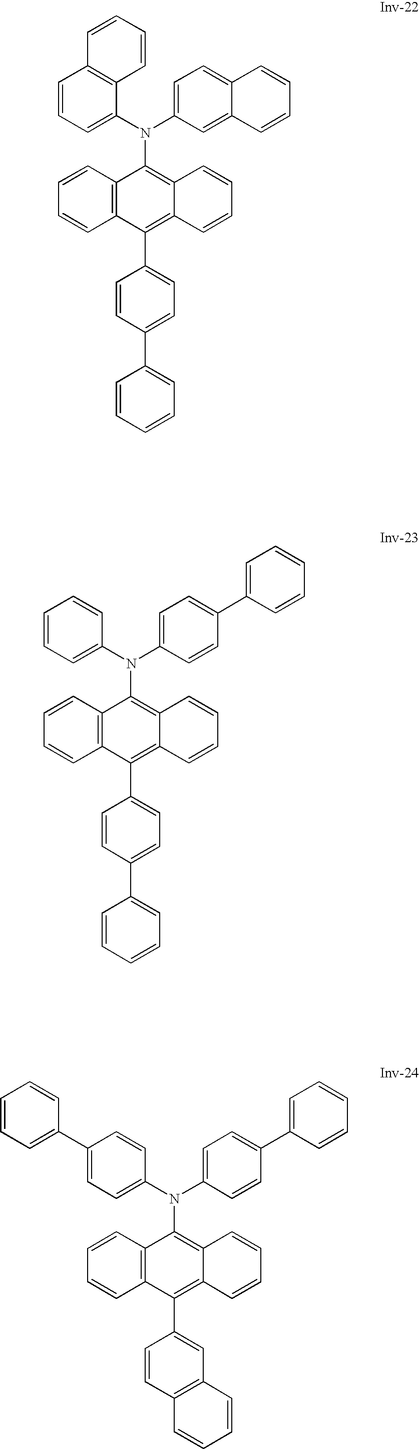 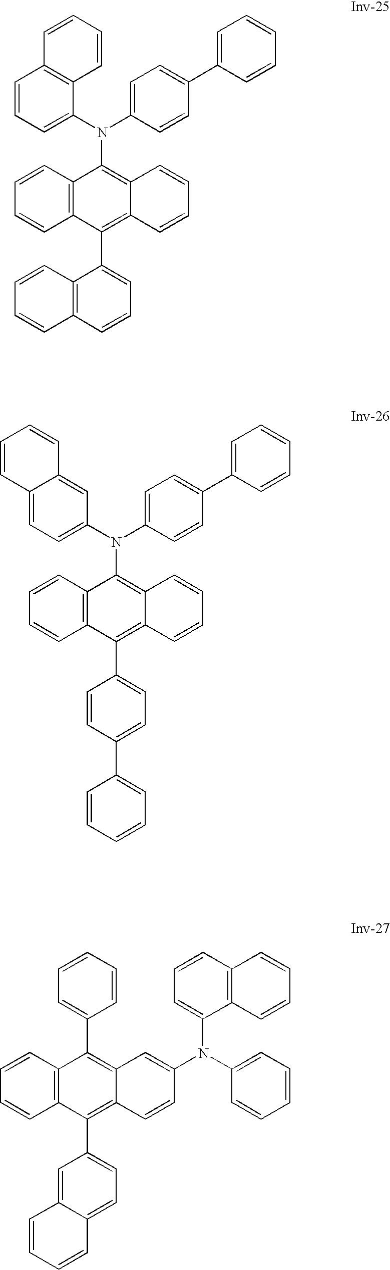 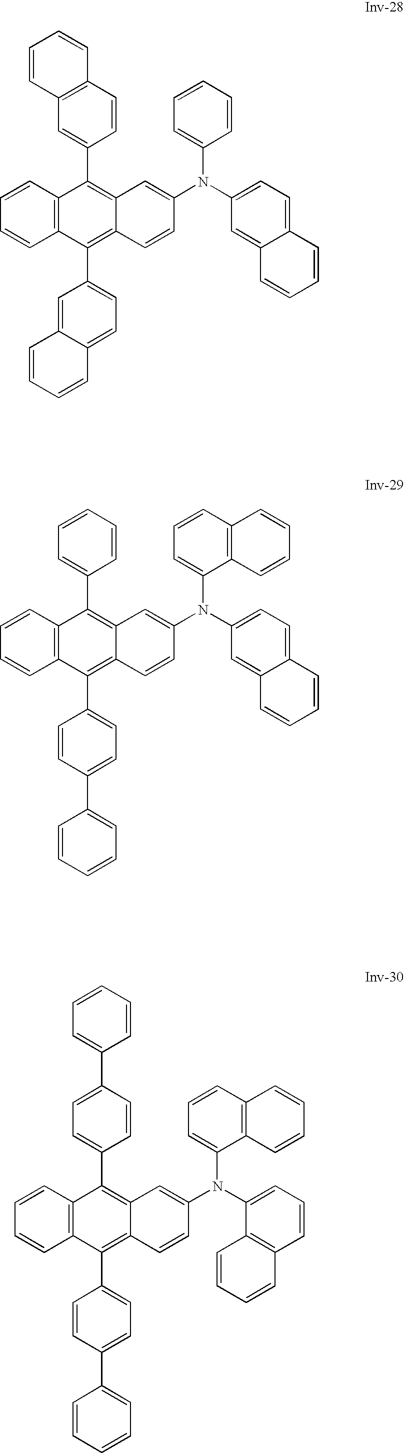 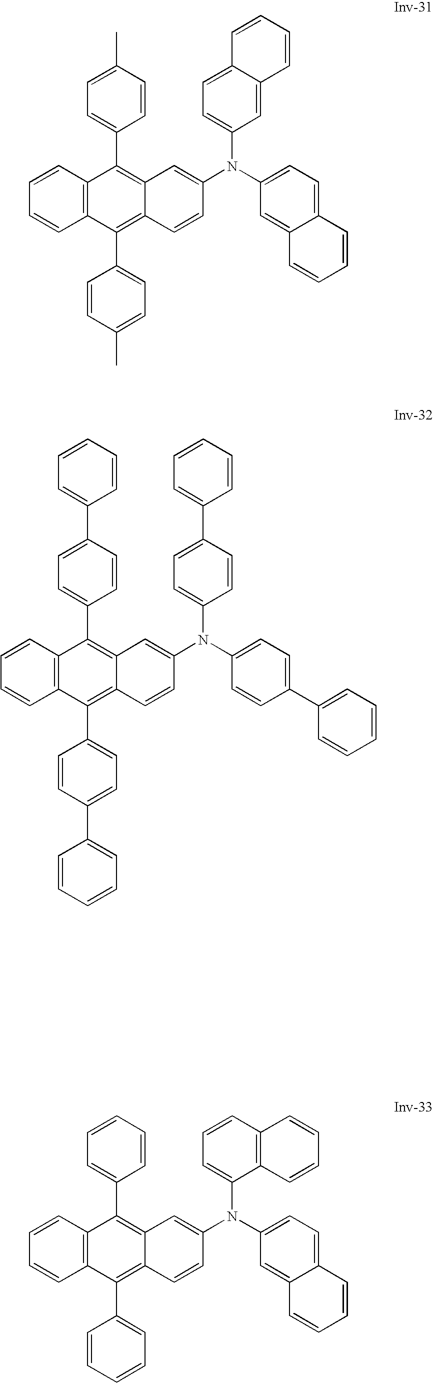 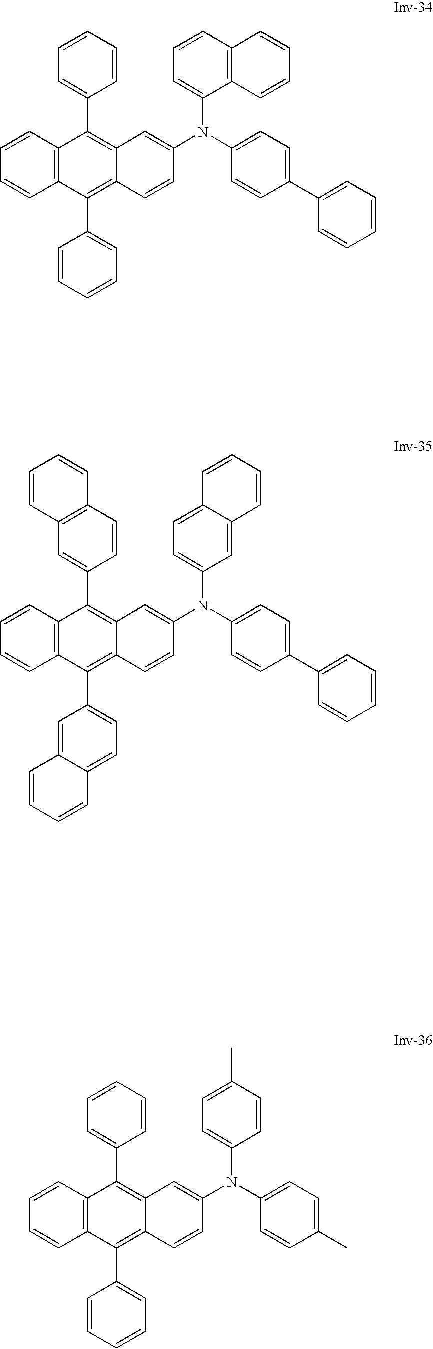 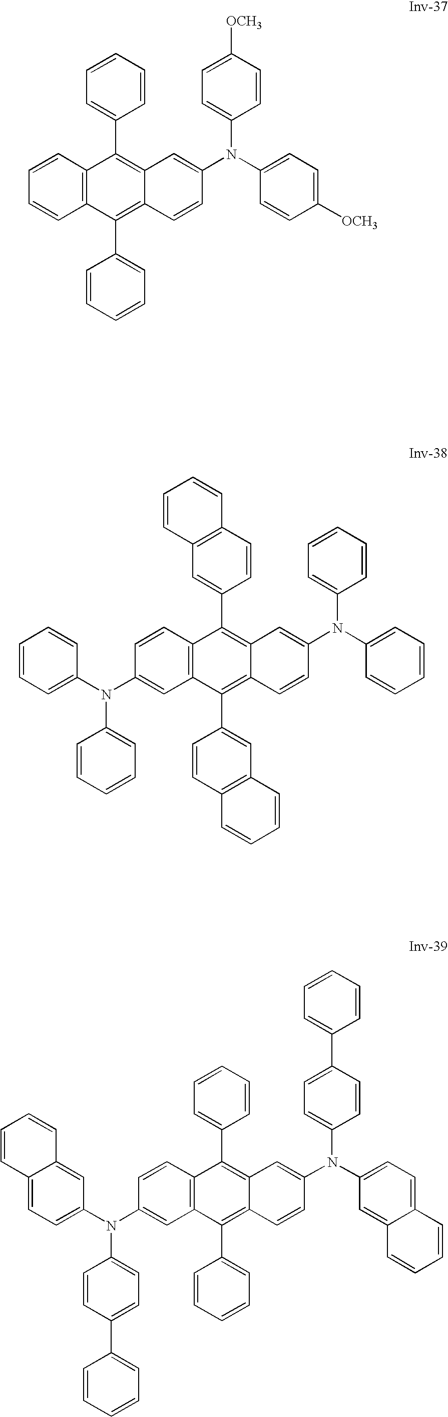 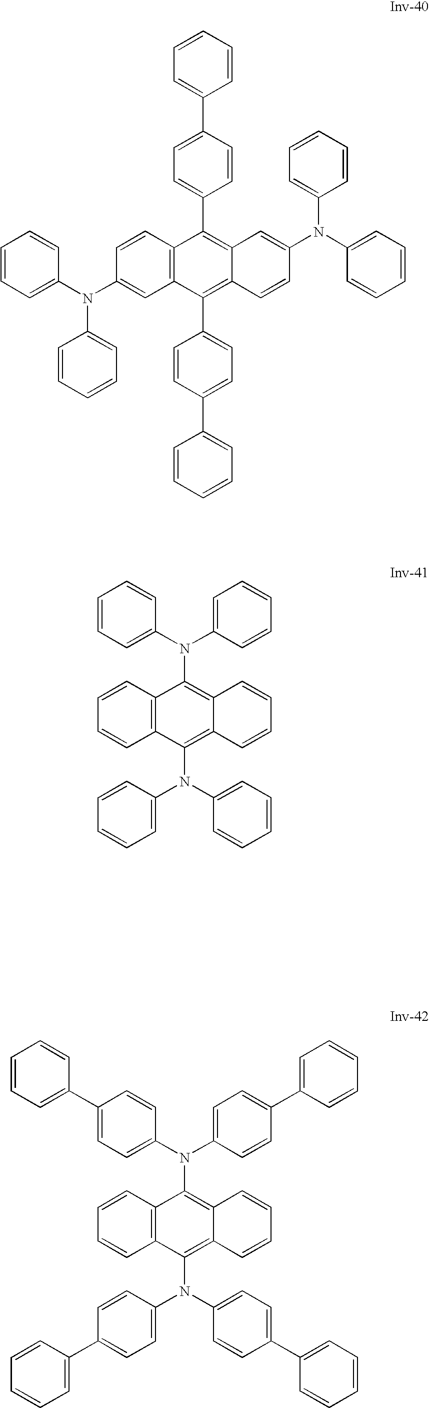 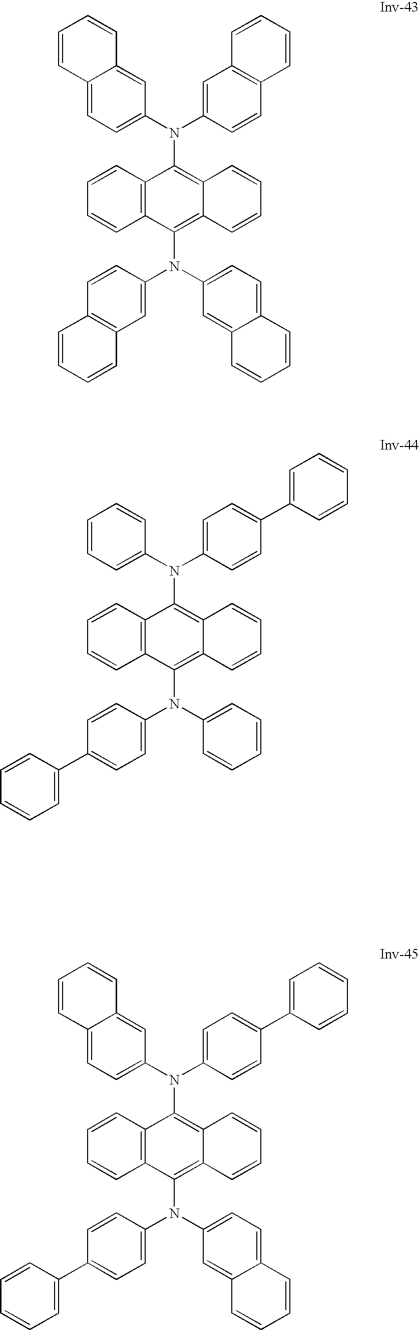
General Device Architecture

The present invention can be employed in many OLED device configurations using small molecule materials, oligomeric materials, polymeric materials, or combinations thereof. These include very simple structures comprising a single anode and cathode to more complex devices, such as passive matrix displays comprised of orthogonal arrays of anodes and cathodes to form pixels, and active-matrix displays where each pixel is controlled independently, for example, with thin film transistors (TFTs).

There are numerous configurations of the organic layers wherein the present invention can be successfully practiced. The essential requirements of an OLED are an anode, a cathode, and an organic light-emitting layer located between the anode and cathode. Additional layers may be employed as more fully described hereafter.

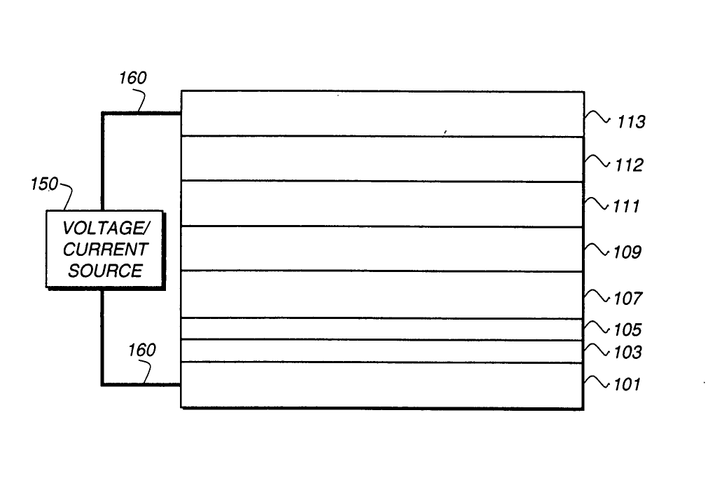

A typical structure, especially useful for of a small molecule device, is shown in FIG. 1 and is comprised of a substrate 101, an anode 103, a hole-injecting layer 105, a hole-transporting layer 107, a light-emitting layer 109, an electron-transporting layer 111, and a cathode 113. These layers are described in detail below. Note that the substrate may alternatively be located adjacent to the cathode, or the substrate may actually constitute the anode or cathode. The organic layers between the anode and cathode are conveniently referred to as the organic EL element. Also, the total combined thickness of the organic layers is desirably less than 500 nm.

The anode and cathode of the OLED are connected to a voltage/current source 150 through electrical conductors 160. The OLED is operated by applying a potential between the anode and cathode such that the anode is at a more positive potential than the cathode. Holes are injected into the organic EL element from the anode and electrons are injected into the organic EL element at the cathode. Enhanced device stability can sometimes be achieved when the OLED is operated in an AC mode where, for some time period in the cycle, the potential bias is reversed and no current flows. An example of an AC driven OLED is described in U.S. Pat. No. 5,552,678.

Substrate

The OLED device of this invention is typically provided over a supporting substrate 101 where either the cathode or anode can be in contact with the substrate. The substrate can be a complex structure comprising multiple layers of materials. This is typically the case for active matrix substrates wherein TFTs are provided below the OLED layers. It is still necessary that the substrate, at least in the emissive pixilated areas, be comprised of largely transparent materials. The electrode in contact with the substrate is conveniently referred to as the bottom electrode. Conventionally, the bottom electrode is the anode, but this invention is not limited to that configuration. The substrate can either be light transmissive or opaque, depending on the intended direction of light emission. The light transmissive property is desirable for viewing the EL emission through the substrate. Transparent glass or plastic is commonly employed in such cases. For applications where the EL emission is viewed through the top electrode, the transmissive characteristic of the bottom support can be light transmissive, light absorbing or light reflective. Substrates for use in this case include, but are not limited to, glass, plastic, semiconductor materials, silicon, ceramics, and circuit board materials. It is necessary to provide in these device configurations a light-transparent top electrode.

Anode

When the desired electroluminescent light emission (EL) is viewed through anode, the anode should be transparent or substantially transparent to the emission of interest. Common transparent anode materials used in this invention are indium-tin oxide (ITO), indium-zinc oxide (IZO) and tin oxide, but other metal oxides can work including, but not limited to, aluminum- or indium-doped zinc oxide, magnesium-indium oxide, and nickel-tungsten oxide. In addition to these oxides, metal nitrides, such as gallium nitride, and metal selenides, such as zinc selenide, and metal sulfides, such as zinc sulfide, can be used as the anode. For applications where EL emission is viewed only through the cathode, the transmissive characteristics of the anode are immaterial and any conductive material can be used, transparent, opaque or reflective. Example conductors for this application include, but are not limited to, gold, iridium, molybdenum, palladium, and platinum. Typical anode materials, transmissive or otherwise, have a work function of 4.1 eV or greater. Desired anode materials are commonly deposited by any suitable means such as evaporation, sputtering, chemical vapor deposition, or electrochemical means. Anodes can be patterned using well-known photolithographic processes. Optionally, anodes may be polished prior to application of other layers to reduce surface roughness so as to minimize shorts or enhance reflectivity.

Hole-Injecting Layer (HIL)

While not always necessary, it is often useful that a hole-injecting layer 105 be provided between anode 103 and hole-transporting layer 107. The hole-injecting material can serve to improve the film formation property of subsequent organic layers and to facilitate injection of holes into the hole-transporting layer. Suitable materials for use in the hole-injecting layer include, but are not limited to, porphyrinic compounds as described in U.S. Pat. No. 4,720,432, plasma-deposited fluorocarbon polymers as described in U.S. Pat. No. 6,208,075, and some aromatic amines, for example, m-MTDATA (4,4′,4″-tris[(3-methylphenyl)phenylamino]triphenylamine). Alternative hole-injecting materials reportedly useful in organic EL devices are described in EP0891121 and EP 1029909.

Hole-Transporting Layer (HTL)

The hole-transporting layer 107 of the organic EL device contains at least one hole-transporting compound, such as an aromatic tertiary amine, where the latter is understood to be a compound containing at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine. Exemplary monomeric triarylamines are illustrated by Klupfel et al. U.S. Pat. No. 3,180,730. Other suitable triarylamines substituted with one or more vinyl radicals and/or comprising at least one active hydrogen containing group are disclosed by Brantley et al U.S. Pat. No. 3,567,450 and U.S. Pat. No. 3,658,520.

A more preferred class of aromatic tertiary amines are those which include at least two aromatic tertiary amine moieties as described in U.S. Pat. No. 4,720,432 and U.S. Pat. No. 5,061,569. Such compounds include those represented by structural formula (A). 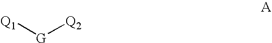
wherein Q₁ and Q₂ are independently selected aromatic tertiary amine moieties and G is a linking group such as an arylene, cycloalkylene, or alkylene group of a carbon to carbon bond. In one embodiment, at least one of Q₁ or Q₂ contains a polycyclic fused ring structure, e.g., a naphthalene. When G is an aryl group, it is conveniently a phenylene, biphenylene, or naphthalene moiety.

A useful class of triarylamines satisfying structural formula (A) and containing two triarylamine moieties is represented by structural formula (B): 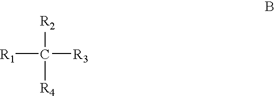
where

R₁ and R₂ each independently represents a hydrogen atom, an aryl group, or an alkyl group or R₁ and R₂ together represent the atoms completing a cycloalkyl group; and

R₃ and R₄ each independently represents an aryl group, which is in turn substituted with a diaryl substituted amino group, as indicated by structural formula (C): 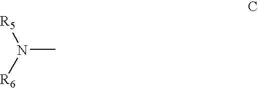
wherein R₅ and R₆ are independently selected aryl groups. In one embodiment, at least one of R₅ or R₆ contains a polycyclic fused ring structure, e.g., a naphthalene.

Another class of aromatic tertiary amines are the tetraaryldiamines. Desirable tetraaryldiamines include two diarylamino groups, such as indicated by formula (C), linked through an arylene group. Useful tetraaryldiamines include those represented by formula (D). 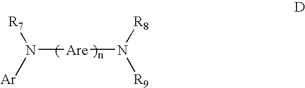
wherein

each Are is an independently selected arylene group, such as a phenylene or anthracene moiety,

n is an integer of from 1 to 4, and

Ar, R₇, R₈, and R₉ are independently selected aryl groups.

In a typical embodiment, at least one of Ar, R₇, R₈, and R₉ is a polycyclic fused ring structure, e.g., a naphthalene

The various alkyl, alkylene, aryl, and arylene moieties of the foregoing structural formulae (A), (B), (C), (D), can each in turn be substituted. Typical substituents include alkyl groups, alkoxy groups, aryl groups, aryloxy groups, and fluoride. The various alkyl and alkylene moieties typically contain from about 1 to 6 carbon atoms. The cycloalkyl moieties can contain from 3 to about 10 carbon atoms, but typically contain five, six, or seven ring carbon atoms—e.g., cyclopentyl, cyclohexyl, and cycloheptyl ring structures. The aryl and arylene moieties are usually phenyl and phenylene moieties.

The hole-transporting layer can be formed of a single or a mixture of aromatic tertiary amine compounds. Specifically, one may employ a triarylamine, such as a triarylamine satisfying the formula (B), in combination with a tetraaryldiamine, such as indicated by formula (D). When a triarylamine is employed in combination with a tetraaryldiamine, the latter is positioned as a layer interposed between the triarylamine and the electron injecting and transporting layer. Illustrative of useful aromatic tertiary amines are the following:
1,1-Bis(4-di-p-tolylaminophenyl)cyclohexane (TAPC)
1,1-Bis(4-di-p-tolylaminophenyl)-4-phenylcyclohexane
4,4′-Bis(diphenylamino)quadriphenyl
Bis(4-dimethylamino-2-methylphenyl)-phenylmethane
N,N,N-Tri(p-tolyl)amine
4-(di-p-tolylamino)-4′-[4(di-p-tolylamino)-styryl]stilbene
N,N,N′,N′-Tetra-p-tolyl-4-4′-diaminobiphenyl
N,N,N′,N′-Tetraphenyl-4,4′-diaminobiphenyl
N,N,N′,N′-tetra-1-naphthyl-4,4′-diaminobiphenyl
N,N,N′,N′-tetra-2-naphthyl-4,4′-diaminobiphenyl
N-Phenylcarbazole
4,4′-Bis[N-(1-naphthyl)-N-phenylamino]biphenyl
4,4′-Bis[N-(1-naphthyl)-N-(2-naphthyl)amino]biphenyl
4,4″-Bis[N-(1-naphthyl)-N-phenylamino]p-terphenyl
4,4′-Bis[N-(2-naphthyl)-N-phenylamino]biphenyl
4,4′-Bis[N-(3-acenaphthenyl)-N-phenylamino]biphenyl
1,5-Bis[N-(1-naphthyl)-N-phenylamino]naphthalene
4,4′-Bis[N-(9-anthryl)-N-phenylamino]biphenyl
4,4″-Bis[N-(1-anthryl)-N-phenylamino]-p-terphenyl
4,4′-Bis[N-(2-phenanthryl)-N-phenylamino]biphenyl
4,4′-Bis[N-(8-fluoranthenyl)-N-phenylamino]biphenyl
4,4′-Bis[N-(2-pyrenyl)-N-phenylamino]biphenyl
4,4′-Bis[N-(2-naphthacenyl)-N-phenylamino]biphenyl
4,4′-Bis[N-(2-perylenyl)-N-phenylamino]biphenyl
4,4′-Bis[N-(1-coronenyl)-N-phenylamino]biphenyl
2,6-Bis(di-p-tolylamino)naphthalene
2,6-Bis[di-(1-naphthyl)amino]naphthalene
2,6-Bis[N-(1-naphthyl)-N-(2-naphthyl)amino]naphthalene
N,N,N′,N′-Tetra(2-naphthyl)-4,4″-diamino-p-terphenyl
4,4′-Bis {N-phenyl-N-[4-(1-naphthyl)-phenyl]amino}biphenyl
4,4′-Bis[N-phenyl-N-(2-pyrenyl)amino]biphenyl
2,6-Bis[N,N-di(2-naphthyl)amine]fluorene
1,5-Bis[N-(1-naphthyl)-N-phenylamino]naphthalene
4,4′,4″-tris[(3-methylphenyl)phenylamino]triphenylamine

Another class of useful hole-transporting materials includes polycyclic aromatic compounds as described in EP 1 009 041. Tertiary aromatic amines with more than two amine groups may be used including oligomeric materials. In addition, polymeric hole-transporting materials can be used such as poly(N-vinylcarbazole) (PVK), polythiophenes, polypyrrole, polyaniline, and copolymers such as poly(3,4-ethylenedioxythiophene)/poly(4-styrenesulfonate) also called PEDOT/PSS.

Light-Emitting Layer (LEL)

As more fully described in U.S. Pat. Nos. 4,769,292 and 5,935,721, the light-emitting layer (LEL) of the organic EL element includes a luminescent fluorescent or phosphorescent material where electroluminescence is produced as a result of electron-hole pair recombination in this region. The light-emitting layer can be comprised of a single material, but more commonly consists of a host material doped with a guest emitting material or materials where light emission comes primarily from the emitting materials and can be of any color. The host materials in the light-emitting layer can be an electron-transporting material, as defined below, a hole-transporting material, as defined above, or another material or combination of materials that support hole-electron recombination. The emitting material is usually chosen from highly fluorescent dyes and phosphorescent compounds, e.g., transition metal complexes as described in WO 98/55561, WO 00/18851, WO 00/57676, and WO 00/70655. Emitting materials are typically incorporated at 0.01 to 10% by weight of the host material.

The host and emitting materials can be small non-polymeric molecules or polymeric materials such as polyfluorenes and polyvinylarylenes (e.g., poly(p-phenylenevinylene), PPV). In the case of polymers, small molecule emitting materials can be molecularly dispersed into a polymeric host, or the emitting materials can be added by copolymerizing a minor constituent into a host polymer.

An important relationship for choosing an emitting material is a comparison of the bandgap potential which is defined as the energy difference between the highest occupied molecular orbital and the lowest unoccupied molecular orbital of the molecule. For efficient energy transfer from the host to the emitting material, a necessary condition is that the band gap of the dopant is smaller than that of the host material. For phosphorescent emitters it is also important that the host triplet energy level of the host be high enough to enable energy transfer from host to emitting material.

Host and emitting materials known to be of use include, but are not limited to, those disclosed in U.S. Pat. No. 4,768,292, U.S. Pat. No. 5,141,671, U.S. Pat. No. 5,150,006, U.S. Pat. No. 5,151,629, U.S. Pat. No. 5,405,709, U.S. Pat. No. 5,484,922, U.S. Pat. No. 5,593,788, U.S. Pat. No. 5,645,948, U.S. Pat. No. 5,683,823, U.S. Pat. No. 5,755,999, U.S. Pat. No. 5,928,802, U.S. Pat. No. 5,935,720, U.S. Pat. No. 5,935,721, and U.S. Pat. No. 6,020,078.

Metal complexes of 8-hydroxyquinoline and similar derivatives (Formula E) constitute one class of useful host compounds capable of supporting electroluminescence, and are particularly suitable for light emission of wavelengths longer than 500 nm, e.g., green, yellow, orange, and red. 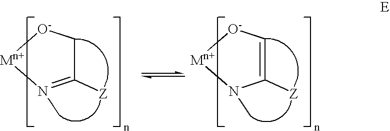
wherein

M represents a metal;

n is an integer of from 1 to 4; and

Z independently in each occurrence represents the atoms completing a nucleus having at least two fused aromatic rings.

From the foregoing it is apparent that the metal can be monovalent, divalent, trivalent, or tetravalent metal. The metal can, for example, be an alkali metal, such as lithium, sodium, or potassium; an alkaline earth metal, such as magnesium or calcium; an earth metal, such aluminum or gallium, or a transition metal such as zinc or zirconium. Generally any monovalent, divalent, trivalent, or tetravalent metal known to be a useful chelating metal can be employed.

Z completes a heterocyclic nucleus containing at least two fused aromatic rings, at least one of which is an azole or azine ring. Additional rings, including both aliphatic and aromatic rings, can be fused with the two required rings, if required. To avoid adding molecular bulk without improving on function the number of ring atoms is usually maintained at 18 or less.

Illustrative of useful chelated oxinoid compounds are the following:
CO-1: Aluminum trisoxine [alias, tris(8-quinolinolato)aluminum(III); Alq]
CO-2: Magnesium bisoxine [alias, bis(8-quinolinolato)magnesium(II)]
CO-3: Bis[benzo{f}-8-quinolinolato]zinc (II)
CO-4: Bis(2-methyl-8-quinolinolato)aluminum(III)-μ-oxo-bis(2-methyl-8-quinolinolato) aluminum(III)
CO-5: Indium trisoxine [alias, tris(8-quinolinolato)indium]
CO-6: Aluminum tris(5-methyloxine) [alias, tris(5-methyl-8-quinolinolato) aluminum(III)]
CO-7: Lithium oxine [alias, (8-quinolinolato)lithium(I)]
CO-8: Gallium oxine [alias, tris(8-quinolinolato)gallium(III)]
CO-9: Zirconium oxine [alias, tetra(8-quinolinolato)zirconium(IV)]

Derivatives of anthracene (Formula F) constitute one class of useful host materials capable of supporting electroluminescence, and are particularly suitable for light emission of wavelengths longer than 400 nm, e.g., blue, green, yellow, orange or red. Asymmetric anthracene derivatives as disclosed in U.S. Pat. No. 6,465,115 and WO 2004/018587 are also useful hosts. 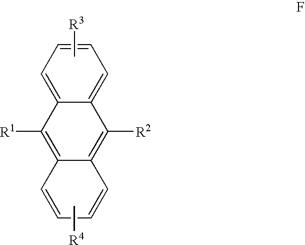
wherein: R¹ and R² represent independently selected aryl groups, such as naphthyl, phenyl, biphenyl, triphenyl, anthracene.

R³ and R⁴ represent one or more substituents on each ring where each substituent is individually selected from the following groups:

Group 1: hydrogen, or alkyl of from 1 to 24 carbon atoms;

Group 2: aryl or substituted aryl of from 5 to 20 carbon atoms;

Group 3: carbon atoms from 4 to 24 necessary to complete a fused aromatic ring of anthracenyl; pyrenyl, or perylenyl;

Group 4: heteroaryl or substituted heteroaryl of from 5 to 24 carbon atoms as necessary to complete a fused heteroaromatic ring of furyl, thienyl, pyridyl, quinolinyl or other heterocyclic systems;

Group 5: alkoxylamino, alkylamino, or arylamino of from 1 to 24 carbon atoms; and

Group 6: fluorine or cyano.

A useful class of anthracenes are derivatives of 9,10-di-(2-naphthyl)anthracene (Formula G). 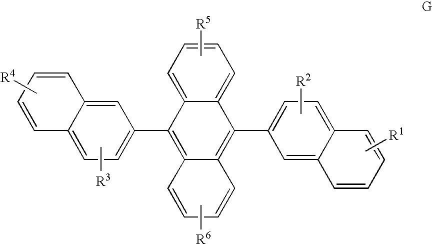
wherein: R¹, R², R³, R⁴, R⁵, and R⁶ represent one or more substituents on each ring where each substituent is individually selected from the following groups:

Group 1: hydrogen, or alkyl of from 1 to 24 carbon atoms;

Group 2: aryl or substituted aryl of from 5 to 20 carbon atoms;

Group 3: carbon atoms from 4 to 24 necessary to complete a fused aromatic ring of anthracenyl; pyrenyl, or perylenyl;

Group 4: heteroaryl or substituted heteroaryl of from 5 to 24 carbon atoms as necessary to complete a fused heteroaromatic ring of furyl, thienyl, pyridyl, quinolinyl or other heterocyclic systems;

Group 5: alkoxylamino, alkylamino, or arylamino of from 1 to 24 carbon atoms; and

Group 6: fluorine or cyano.

Illustrative examples of anthracene materials for use in a light-emitting layer include: 2-(4-methylphenyl)-9,10-di-(2-naphthyl)-anthracene; 2-phenyl-9,10-di-(2-naphthyl)-anthracene; 9-(2-naphthyl)-10-(1,1′-biphenyl)-anthracene; 10-(4-biphenyl)-9-(2-naphthyl)anthracene; 9,10-bis[4-(2,2-diphenylethenyl)phenyl]-anthracene;

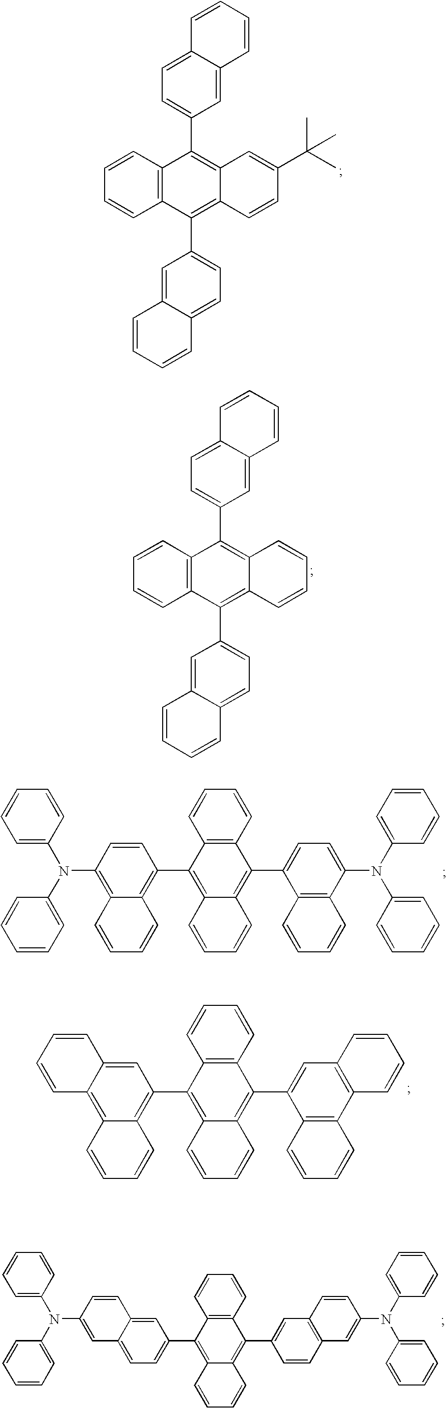

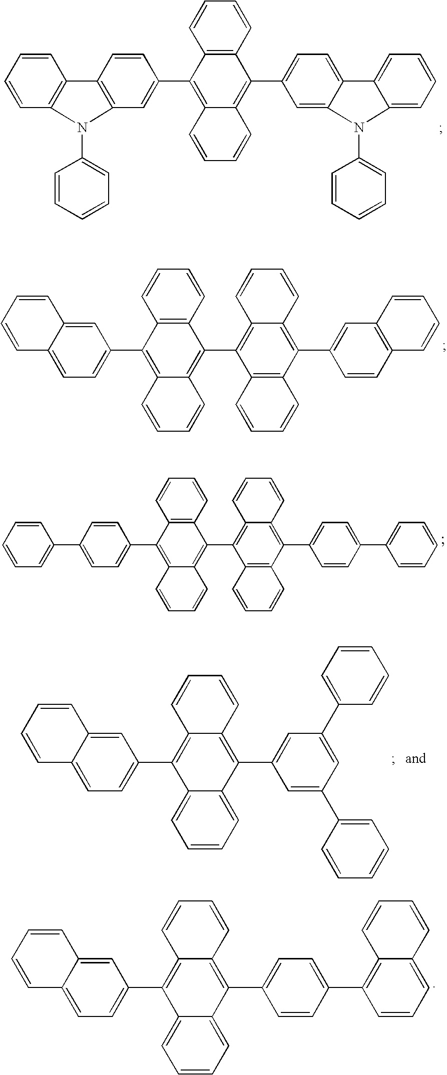

Benzazole derivatives (Formula H) constitute another class of useful host materials capable of supporting electroluminescence, and are particularly suitable for light emission of wavelengths longer than 400 nm, e.g., blue, green, yellow, orange or red. 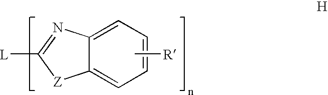
Where:

n is an integer of 3 to 8;

Z is O, NR or S; and

R and R′ are individually hydrogen; alkyl of from 1 to 24 carbon atoms, for example, propyl, t-butyl, heptyl, and the like; aryl or hetero-atom substituted aryl of from 5 to 20 carbon atoms for example phenyl and naphthyl, furyl, thienyl, pyridyl, quinolinyl and other heterocyclic systems; fluoro; or atoms necessary to complete a fused aromatic ring;

L is a linkage unit consisting of alkyl, aryl, substituted alkyl, or substituted aryl, which conjugately or unconjugately connects the multiple benzazoles together. An example of a useful benzazole is 2,2′,2″-(1,3,5-phenylene)tris[1-phenyl-1H-benzimidazole].

Distyrylarylene derivatives are also useful hosts, as described in U.S. Pat. No. 5,121,029. Carbazole derivatives are particularly useful hosts for phosphorescent emitters.

Useful fluorescent emitting materials include, but are not limited to, derivatives of anthracene, tetracene, xanthene, perylene, rubrene, coumarin, rhodamine, and quinacridone, dicyanomethylenepyran compounds, thiopyran compounds, polymethine compounds, pyrilium and thiapyrilium compounds, fluorene derivatives, periflanthene derivatives, indenoperylene derivatives, bis(azinyl)amine boron compounds, bis(azinyl)methane compounds, and carbostyryl compounds. Illustrative examples of useful materials include, but are not limited to, the following:

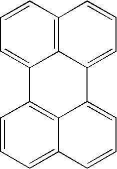

L1

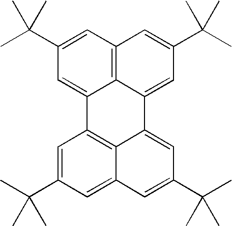

L2

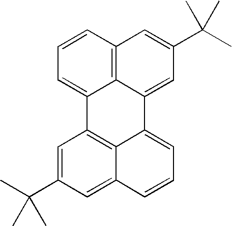

L3

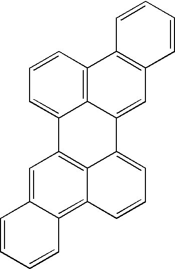

L4

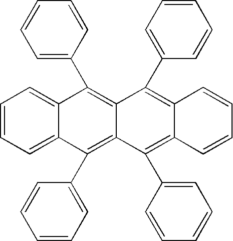

L5

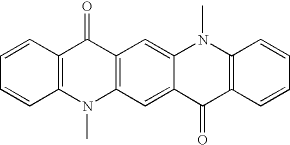

L6

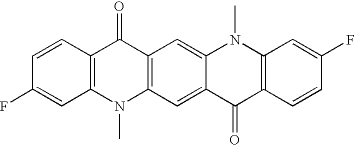

L7

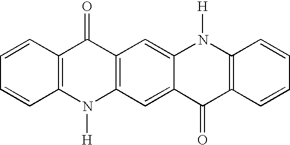

L8

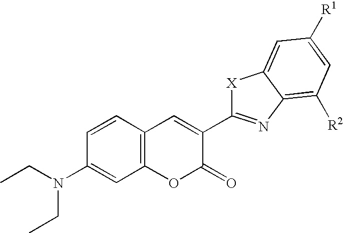

| | X | R1 | R2 |
|---|---|---|---|
| L9 | O | H | H |
| L10 | O | H | Methyl |
| L11 | O | Methyl | H |
| L12 | O | Methyl | Methyl |
| L13 | O | H | t-butyl |
| L14 | O | t-butyl | H |
| L15 | O | t-butyl | t-butyl |
| L16 | S | H | H |
| L17 | S | H | Methyl |
| L18 | S | Methyl | H |
| L19 | S | Methyl | Methyl |
| L20 | S | H | t-butyl |
| L21 | S | t-butyl | H |
| L22 | S | t-butyl | t-butyl |

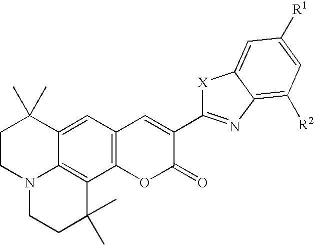

| | X | R1 | R2 |
|---|---|---|---|
| L23 | O | H | H |
| L24 | O | H | Methyl |
| L25 | O | Methyl | H |
| L26 | O | Methyl | Methyl |
| L27 | O | H | t-butyl |
| L28 | O | t-butyl | H |
| L29 | O | t-butyl | t-butyl |
| L30 | S | H | H |
| L31 | S | H | Methyl |
| L32 | S | Methyl | H |
| L33 | S | Methyl | Methyl |
| L34 | S | H | t-butyl |
| L35 | S | t-butyl | H |
| L36 | S | t-butyl | t-butyl |

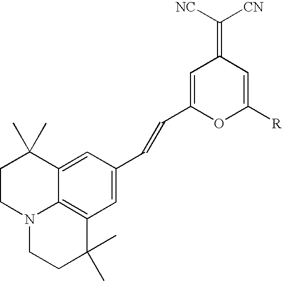

| | R |
|---|---|
| L37 | phenyl |
| L38 | methyl |
| L39 | t-butyl |
| L40 | mesityl |

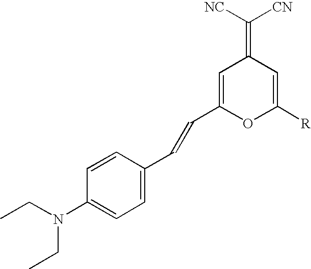

| | R |
|---|---|
| L41 | phenyl |
| L42 | methyl |
| L43 | t-butyl |
| L44 | mesityl |

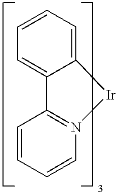

L45

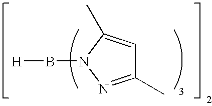

L46

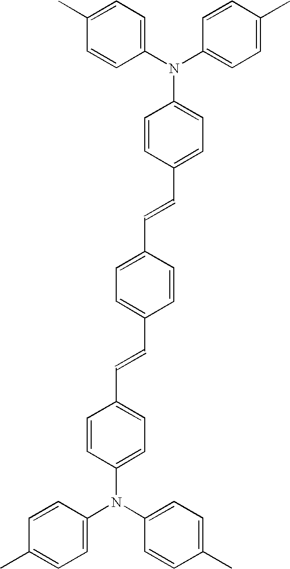

L47

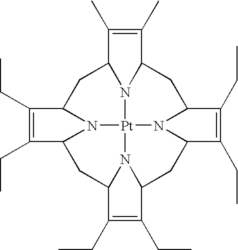

L48

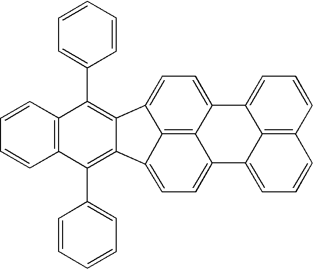

L49

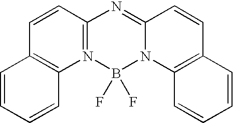

L50

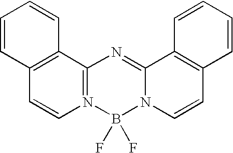

L51

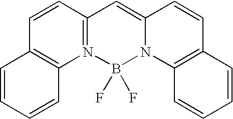

L52

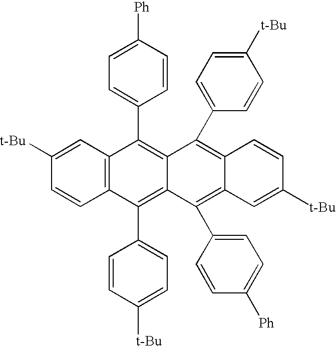

L53

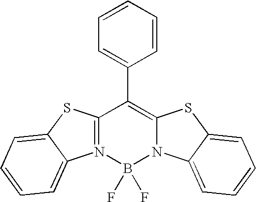

L54

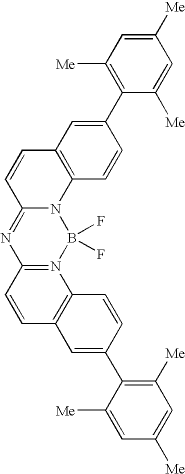

L55

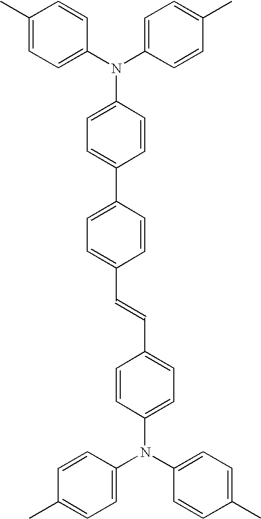

L56

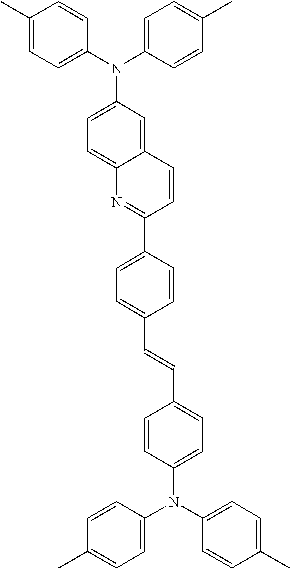

L57

Electron-Transporting Layer (ETL)

Common thin film-forming materials for use in forming the electron-transporting layer of the organic EL devices are metal chelated oxinoid compounds, including chelates of oxine itself (also commonly referred to as 8-quinolinol or 8-hydroxyquinoline). Such compounds help to inject and transport electrons and exhibit both high levels of performance and are readily fabricated in the form of thin films. Exemplary of contemplated oxinoid compounds are those satisfying structural formula (E), previously described.

Other electron-transporting materials include various butadiene derivatives as disclosed in U.S. Pat. No. 4,356,429 and various heterocyclic optical brighteners as described in U.S. Pat. No. 4,539,507. Benzazoles satisfying structural formula (H) are also useful electron transporting materials. Triazines are also known to be useful as electron transporting materials.

Cathode

When light emission is viewed solely through the anode, the cathode used in this invention can be comprised of nearly any conductive material. Desirable materials have good film-forming properties to ensure good contact with the underlying organic layer, promote electron injection at low voltage, and have good stability. Useful cathode materials often contain a low work function metal (<4.0 eV) or metal alloy. One useful cathode material is comprised of a Mg:Ag alloy wherein the percentage of silver is in the range of 1 to 20%, as described in U.S. Pat. No. 4,885,221. Another suitable class of cathode materials includes bilayers comprising a cathode material and a thin inorganic electron-injecting layer in contact with an organic layer (e.g., an electron transporting layer (ETL) which is capped with a thicker layer of a conductive metal. Here, the cathode bilayer desirably includes a low work function metal or metal salt, and if so, the thicker capping layer does not need to have a low work function. One such bilayer cathode is comprised of a thin layer of LiF followed by a thicker layer of Al as described in U.S. Pat. No. 5,677,572. Other useful cathode material sets include, but are not limited to, those disclosed in U.S. Pat. Nos. 5,059,861; 5,059,862, and 6,140,763.

When light emission is viewed through the cathode, the cathode must be transparent or nearly transparent. For such applications, metals must be thin or one must use transparent conductive oxides, or a combination of these materials. Optically transparent cathodes have been described in more detail in U.S. Pat. No. 4,885,211, U.S. Pat. No. 5,247,190, JP 3,234,963, U.S. Pat. No. 5,703,436, U.S. Pat. No. 5,608,287, U.S. Pat. No. 5,837,391, U.S. Pat. No. 5,677,572, U.S. Pat. No. 5,776,622, U.S. Pat. No. 5,776,623, U.S. Pat. No. 5,714,838, U.S. Pat. No. 5,969,474, U.S. Pat. No. 5,739,545, U.S. Pat. No. 5,981,306, U.S. Pat. No. 6,137,223, U.S. Pat. No. 6,140,763, U.S. Pat. No. 6,172,459, EP 1 076 368, U.S. Pat. No. 6,278,236, and U.S. Pat. No. 6,284,3936. Cathode materials are typically deposited by any suitable method such as evaporation, sputtering, or chemical vapor deposition. When needed, patterning can be achieved through many well known methods including, but not limited to, through-mask deposition, integral shadow masking as described in U.S. Pat. No. 5,276,380 and EP 0 732 868, laser ablation, and selective chemical vapor deposition.

Other Useful Organic Layers and Device Architecture

In some instances, layers 109 and 111 can optionally be collapsed into a single layer that serves the function of supporting both light emission and electron transportation. It also known in the art that emitting materials may be included in the hole-transporting layer, which may serve as a host. Multiple materials may be added to one or more layers in order to create a white-emitting OLED, for example, by combining blue- and yellow-emitting materials, cyan- and red-emitting materials, or red-, green-, and blue-emitting materials. White-emitting devices are described, for example, in EP 1 187 235, US 20020025419, EP 1 182 244, U.S. Pat. No. 5,683,823, U.S. Pat. No. 5,503,910, U.S. Pat. No. 5,405,709, and U.S. Pat. No. 5,283,182 and may be equipped with a suitable filter arrangement to produce a color emission.

Additional layers such as electron or hole-blocking layers as taught in the art may be employed in devices of this invention. Hole-blocking layers may be used between the light emitting layer and the electron transporting layer. Electron-blocking layers may be used between the hole-transporting layer and the light emitting layer. These layers are commonly used to improve the efficiency of emission, for example, as in US 20020015859. In some embodiments of the invention, the device includes a layer 112 contiguous to the cathode.

This invention may be used in so-called stacked device architecture, for example, as taught in U.S. Pat. No. 5,703,436 and U.S. Pat. No. 6,337,492.

Deposition of Organic Layers

The organic materials mentioned above are suitably deposited by any means suitable for the form of the organic materials. In the case of small molecules, they are conveniently deposited through sublimation, but can be deposited by other means such as from a solvent with an optional binder to improve film formation. If the material is a polymer, solvent deposition is usually preferred. The material to be deposited by sublimation can be vaporized from a sublimator “boat” often comprised of a tantalum material, e.g., as described in U.S. Pat. No. 6,237,529, or can be first coated onto a donor sheet and then sublimed in closer proximity to the substrate. Layers with a mixture of materials can utilize separate sublimator boats or the materials can be pre-mixed and coated from a single boat or donor sheet. Patterned deposition can be achieved using shadow masks, integral shadow masks (U.S. Pat. No. 5,294,870), spatially-defined thermal dye transfer from a donor sheet (U.S. Pat. No. 5,688,551, U.S. Pat. No. 5,851,709 and U.S. Pat. No. 6,066,357) and inkjet method (U.S. Pat. No. 6,066,357).

One preferred method for depositing the materials of the present invention is described in US 2004/0255857 and U.S. Ser. No. 10/945,941 where different source evaporators are used to evaporate each of the materials of the present invention. A second preferred method involves the use of flash evaporation where materials are metered along a material feed path in which the material feed path is temperature controlled. Such a preferred method is described in the following co-assigned patent applications: U.S. Ser. No. 10/784,585; U.S. Ser. No. 10/805,980; U.S. Ser. No. 10/945,940; U.S. Ser. No. 10/945,941; U.S. Ser. No. 11/050,924; and U.S. Ser. No. 11/050,934. Using this second method, each material may be evaporated using different source evaporators or the solid materials may be mixed prior to evaporation using the same source evaporator

Encapsulation

Most OLED devices are sensitive to moisture or oxygen, or both, so they are commonly sealed in an inert atmosphere such as nitrogen or argon, along with a desiccant such as alumina, bauxite, calcium sulfate, clays, silica gel, zeolites, alkaline metal oxides, alkaline earth metal oxides, sulfates, or metal halides and perchlorates. Methods for encapsulation and desiccation include, but are not limited to, those described in U.S. Pat. No. 6,226,890. In addition, barrier layers such as SiOx, Teflon, and alternating inorganic/polymeric layers are known in the art for encapsulation.

Optical Optimization

OLED devices of this invention can employ various well-known optical effects in order to enhance its properties if desired. This includes optimizing layer thicknesses to yield maximum light transmission, providing dielectric mirror structures, replacing reflective electrodes with light-absorbing electrodes, providing anti glare or anti-reflection coatings over the display, providing a polarizing medium over the display, or providing colored, neutral density, or color conversion filters over the display. Filters, polarizers, and anti-glare or anti-reflection coatings may be specifically provided over the cover or as part of the cover.

Aminoanthracenes can be synthesized by a variety of ways. One particular way is outlined below in Synthetic Scheme (I). In this example, 9-bromoanthracene is coupled with a particular aryl group using Suzuki cross coupling to form Int-A. Int-A is brominated to provide Int-B; which is followed by Pd catalyzed cross coupling with an amine to make IC-1, one class of materials useful in the present invention.

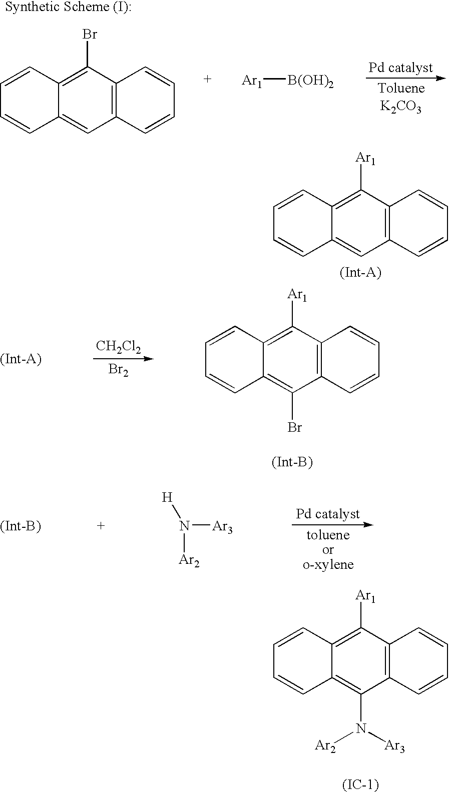

Aminoanthracenes can also be synthesized according to Synthetic Scheme (II). In this example 2-amino-anthraquinone is converted to 2-bromo-anthraquinone (Int-C) using the Sandmeyer Reaction. Int-C is then coupled with an aromatic amine using palladium chemistry to produce Int-D. Alternatively, Int-D can be synthesized directly from 2-amino-anthraquinone using the Ullman coupling. Reaction of Int-D with either an aryl grignard reagant or aryllithium reagant followed by reduction of the resulting diol leads to IC-2, another class of materials useful in the present invention.

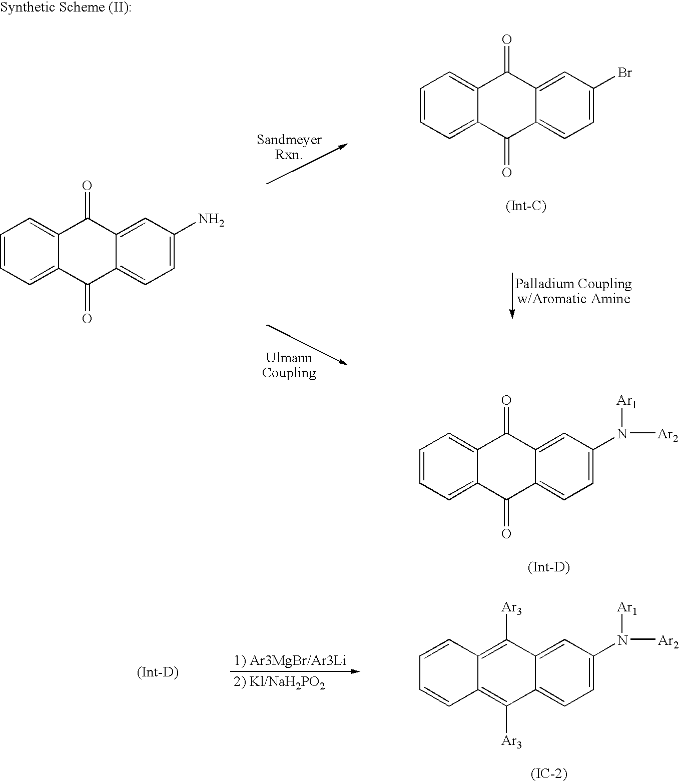

Aminoanthracenes can also be synthesized according to Synthetic Scheme (III). In this example, 2,6-dibromoanthraquinone undergoes palladium catalyzed cross coupling with an aromatic amine to produce Int-E. Int-E is reacted with either an aryl grignard reagant or an aryllithium reagant to produce a diol which is then reduced to produce IC-3, another class of materials useful in the present invention. 2,6-dibromoanthraquinone may be synthesized from 2,6-diaminoanthraquinone using the Sandmeyer reaction. IC-3 may also be synthesized in one step by using the Ullman coupling from the starting 2,6-diaminoanthraquinone.

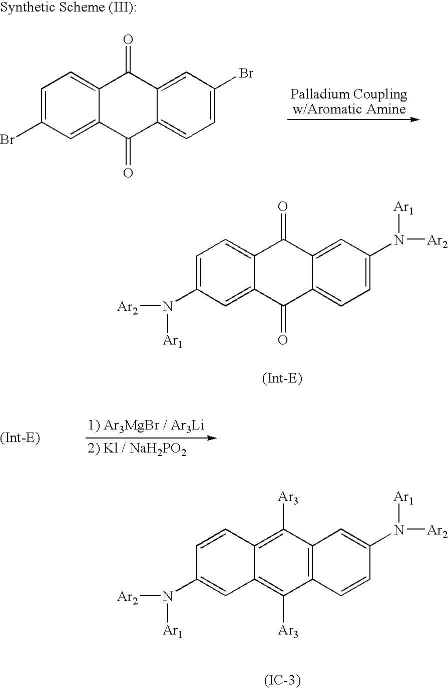

Aminoanthracenes can also be synthesized according to Synthetic Scheme (IV). In this example, 9,10-dibromoanthracene undergoes palladium catalyzed cross coupling with an aromatic amine to produce IC-4, another class of materials useful in the present invention.

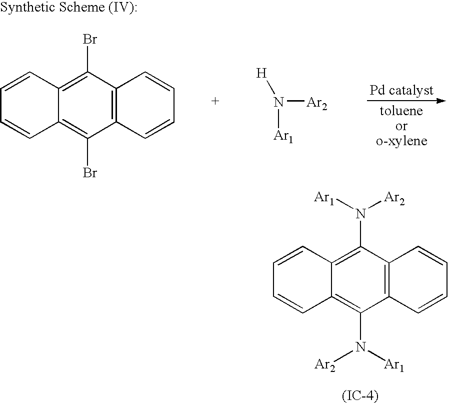

### EXAMPLES

### Synthesis Examples

### 9-(2-naphthylenyl)anthracene

9-bromoanthracene (25.0 g, 0.088 mol), 2-naphthylboronic acid (17.1 g, 0.099 mol), tetrakis(triphenylphosphine)palladium(0) (0.7 g), 300 ml toluene and 150 ml potassium carbonate (2N) were all added to a round bottom flask under a nitrogen atmosphere. Reaction was heated at reflux for two days. Thin layer chromatography (TLC), using hexane: dichloromethane (6:1 ratio) as eluent showed 9-bromoanthracene was no longer present. Reaction cooled to room temperature and gray solid collected by filtration and washed very well with water. This solid was heated lightly in HCl (6M) for 2 hours after which the solid was collected by filtration, washed well with water and dried. Gray solid suspended in dichloromethane and heated gently. Suspension filtered and washed well with dichloromethane. Filtrate is rotary evaporated and the resulting yellow solid is sonicated in diethyl ether for 60 minutes. The yellow solid is collected by filtration, washed with diethyl ether and then dried in oven to yield 16.7 g (62% yield) of pure yellow product. FD-MS (m/z): 304.

### 9-bromo-10-(2-naphthylenyl)anthracene

9-(2-naphthylenyl)anthracene (24.5 g, 0.081 mol) was dissolved in 400 ml dichloromethane. Bromine (13.0 g, 0.081 mol) dissolved in 100 ml dichloromethane was added dropwise over 30 minutes and solution was stirred at room temperature overnight. Dichloromethane is removed by rotary evaporation and methanol (250 ml) is added to the flask. Suspension is filtered and yellow solid is washed with methanol and dried to yield 30 g (97% yield) of pure yellow product. FD-MS (m/z): 383.

### N,10-(2-naphthalenyl)-N′-phenyl-9-anthraceneamine (Inv-2)

9-bromo-10-(2-naphthylenyl)anthracene (5.0 g, 0.013 mol), N-phenyl-2-naphthylamine (3.2 g, 0.014 mol), 1.75 g sodium tert-butoxide, 0.16 g palladium(II) acetate, 2 drops tri-tert-butylphosphine and 25 ml o-xylene are added to a round bottom flask under a nitrogen atmosphere. Mixture heated at 100° C. overnight. After cooling to room temperature, insoluble materials are filtered off. Xylene is distilled away and remaining solid is chromatagraphed on a silica gel column to yield 6.0 g (88% yield) of pure yellow product. FD-MS (m/z): 521.

### N,N′-di-2-naphthalenyl-N,N′-diphenyl-9,10-anthracenediamine (Inv-3)

9,10-dibromoanthracene (1.0 g, 0.003 mol), N-phenyl-2-naphthylamine (1.43 g, 0.007 mol), 0.7 g sodium tert-butoxide, 0.04 g palladium(II) acetate, 0.03 g tri-tert-butylphosphine and 40 ml o-xylenes are added to a round bottom flask under a nitrogen atmosphere. Mixture heated at reflux overnight. After cooling, ethanol added and solid collected by filtration and washed well with ethanol. Collected solid chromatographed on a silica gel column to yield 1.68 g of pure yellow product. FD-MS (m/z): 612.

### N,N,9,10-tetraphenyl-2-anthraceneamine (Inv-6)

### (Step 1) 2-(diphenylamino)-9,10-Anthracenedione

2-aminoanthraquinone (5 g, 0.022 mol), iodobenzene (10.0 g, 0.05 mol), bromobenzene (20.0 ml), copper (2.0 g), and potassium carbonate (6.5 g, 0.05 mol) refluxed under a nitrogen atmosphere for 4 days. Hot solution is passed thru a fritted funnel. Upon cooling, funnel is washed well with methylene chloride and filtrate is rotary evaporated until there is mostly solid present. Acetone is added the red solids are collected by filtration to yield 6.0 g, 72% yield. FD-MS (m/z): 375.

### (Step 2) N,N,9,10-tetraphenyl-2-anthraceneamine (Inv-10)

2-(diphenylamino)-9,10-Anthracenedione (1.2 g, 0.003 mol) and anhydrous tetrahydrofuran (15 ml) are placed into a round bottom flask under a nitrogen atmosphere and cooled to 0° C. Phenyllithium (5.3 ml, 1.8M in cyclohexane-ether, 70:30) added dropwise. Temperature allowed to warm to room temperature overnight with stirring. Poured reaction mixture to water. After extraction with diethyl ether, the organic layer is dried over magnesium sulfate and solvent removed by rotary evaporation to produce a crude solid. The crude diol is dissolved in 32 ml acetic acid. Sodium iodide (4.8 g), and sodium hypophosphite hydrate (4.8 g) were added with stirring. Mixture heated to reflux for 60 minutes, cooled to room temperature and poured to water. The precipitated solid was collected by filtration, washed with water, washed with a small amount of methanol (˜20 ml) and is then dried. Purification by column chromatography yielded 0.95 g of pure product, 60% yield, as an orange solid. FD-MS (m/z): 497

### N,10-phenyl-N′-(2-naphthalenyl)-9-anthraceneamine (Inv-9)

9-bromo-10-phenylanthracene (1.5 g, 0.005 mol), N-phenyl-2-naphthylamine (0.005 mol), 0.5 g sodium tert-butoxide, 0.1 g palladium(II) acetate, 2 drops tri-tert-butylphosphine and 40 ml toluene are added to a round bottom flask under a nitrogen atmosphere. Mixture heated at reflux for 2 days. After cooling, toluene removed by rotary evaporation and remaining solid chromatographed on a silica gel column to yield 1.6 g (75% yield) of pure yellow product. FD-MS (m/z): 471.

### 10-(2-naphthalenyl)-N,N-diphenyl-9-anthraceneamine (Inv-10)

9-bromo-10-(2-naphthylenyl)anthracene (3.3 g, 0.008 mol), diphenylamine (1.5 g, 0.008 mol), 1.0 g sodium tert-butoxide, 0.1 g palladium(II) acetate, 3 drops tri-tert-butylphosphine and 80 ml toluene are added to a round bottom flask under a nitrogen atmosphere. Mixture heated at reflux for 2 days. After cooling, toluene removed by rotary evaporation and remaining solid chromatographed on a silica gel column to yield 4.0 g (99% yield) of pure yellow product. FD-MS (m/z): 471.

### 10-[1,1′-biphenyl]-4-yl-N-phenyl-N′-(2-naphthalenyl)-9-anthraceneamin (Inv-11)

9-bromo-10-[1,1′-biphenyl]-4-yl-anthracene (7.0 g, 0.017 mol), N-phenyl-2-naphthylamine (3.5 g, 0.017 mol), 2.7 g sodium tert-butoxide, 1.0 g palladium(II) acetate, 6 drops tri-tert-butylphosphine and 120 ml toluene are added to a round bottom flask under a nitrogen atmosphere. Mixture heated at reflux for 1 day. After cooling, methanol added and solid collected by filtration and dried. Solid was chromatographed on a silica gel column to yield 7.0 g (75% yield) of pure yellow product. FD-MS (m/z): 547.

### Device Examples

### Example 1

Preparation of Devices 1-1 through 1-4.

A series of EL devices (1-1 through 1-3) were constructed in the following manner.
1. A glass substrate coated with a 25 nm layer of indium-tin oxide (ITO), as the anode, was sequentially ultrasonicated in a commercial detergent, rinsed in deionized water, degreased in toluene vapor and exposed to oxygen plasma for about 1 min.
2. Over the ITO was deposited a 1 nm fluorocarbon (CFx) hole-injecting layer (HIL) by plasma-assisted deposition of CHF₃ as described in U.S. Pat. No. 6,208,075.
3. Next a layer of hole-transporting material 4,4′-Bis[N-(1-naphthyl)-N-phenylamino]biphenyl (NPB) was deposited to a thickness of 75 nm.
4. A 20 nm light-emitting layer (LEL) corresponding to 10-(4-biphenyl)-9-(2-naphthyl)anthracene and light-emitting material, L-55 at 1 wt %, was then deposited.
5. A 40 nm electron-transporting layer (ETL) of a material shown in Table 1 was vacuum-deposited over the LEL.
6. 0.5 nm of lithium fluoride was vacuum deposited onto the ETL, followed by a 100 nm layer of aluminum, to form a bilayer cathode.

The above sequence completes the deposition of the EL device. The device is then hermetically packaged in a dry glove box for protection against ambient environment.

Device 1-4 was constructed in an identical manner to device 1-1 except the ETL was a 37.5 nm layer of Inv-10 and a 2.5 nm layer of Bphen, where the Bphen was adjacent to the lithium fluoride.

The devices were tested for operational voltage and luminous efficiency at an operating current of 20 mA/cm². The results are reported in Table 1 in the form of voltage (V), luminous yield (cd/A) and efficiency (w/A), where device efficiency is the radiant flux (in watts) produced by the device per amp of input current, where radiant flux is the light energy produced by the device per unit time. Light intensity is usually measured perpendicular to the device surface, and it is assumed that the angular profile is Lambertian. The devices were also tested for operational lifetime. They were operated at 40 mA/cm² at room temperature with an AC Drive at 100 Hz with a −14 V reverse bias. The lifetime to T₇₀ is shown in Table 1 as the number of hours the device operated before the light output dropped to 70% of its initial light output.

TABLE 1
Evaluation results for Devices 1-1 through 1-4.

| | | | | Luminous | | |
|---|---|---|---|---|---|---|
| | | | Voltage | Yield | Efficiency | T₇₀ |
| Device | Example | ETL | (V) | (cd/A) | (W/A) | (h) |
| 1-1 | Comparative | Alq | 7.8 | 3.44 | 0.068 | 577 |
| 1-2 | Comparative | Bphen | 5.7 | 5.29 | 0.132 | 6 |
| 1-3 | Comparative | Inv-10 | 11.2 | 2.41 | 0.051 | 300 |
| 1-4 | Inventive | 2-layer | 5.1 | 5.74 | 0.115 | 133 |
| | | Inv-10/ | | | | |
| | | Bphen | | | | |

Device 1-4 shows a large improvement of voltage and efficiency with some loss in stability compared to Alq (Device 1-1). The use of only Bphen as the ETL (Device 1-2) offers a similar improvement in voltage and efficiency, but suffers from a catastrophic decrease in device operational lifetime. The use of only Inv-10 as the ETL (Device 1-3) does not exhibit the improved voltage and efficiency, showing the desirability of the two-layer structure.

### Example 2

Preparation of Device 2-1 through 2-4.

Devices 2-1 through 2-3 were constructed in an identical manor as device 1-1 except the ETL was a compound shown in Table 2.

Device 2-4 was constructed in an identical manner to device 1-1 except the ETL was a 37.5 nm layer of Inv-3 and a 2.5 nm layer of Bphen, where the Bphen was adjacent to the lithium fluoride.

The devices were tested for operational voltage and luminous efficiency at an operating current of 20 mA/cm². The results are reported in Table 2 in the form of voltage (V), luminous yield (cd/A) and efficiency (w/A), where device efficiency is the radiant flux (in watts) produced by the device per amp of input current, where radiant flux is the light energy produced by the device per unit time. Light intensity is usually measured perpendicular to the device surface, and it is assumed that the angular profile is Lambertian. The devices were also tested for operational lifetime. They were operated at 40 mA/cm² at room temperature with an AC Drive at 100 Hz with a −14 V reverse bias. The lifetime to T₇₀ is shown in Table 2 as the number of hours the device operated before the light output dropped to 70% of its initial light output.

TABLE 2
Evaluation results for Devices 2-1 through 2-4.

| | | | | Luminous | | |
|---|---|---|---|---|---|---|
| | | | Voltage | Yield | Efficiency | T₇₀ |
| Device | Example | ETL | (V) | (cd/A) | (W/A) | (h) |
| 2-1 | Comparative | Alq | 10.6 | 4.3 | 0.090 | 219 |
| 2-2 | Comparative | Bphen | 6.5 | 6.01 | 0.144 | 2 |
| 2-3 | Comparative | Inv-3 | 10.0 | 4.53 | 0.083 | 148 |
| 2-4 | Inventive | 2-layer | 6.1 | 5.07 | 0.098 | 68 |
| | | Inv-3/ | | | | |
| | | Bphen | | | | |

Device 2-4 shows a large improvement of voltage and efficiency compared to Alq (Device 2-1). The use of only Bphen as the ETL (Device 2-2) offers a similar improvement in voltage and efficiency, but suffers from a catastrophic decrease in device operational lifetime. The use of only Inv-3 as the ETL (Device 2-3) does not exhibit the improved voltage and efficiency, showing the desirability of the two layer structure.

### Example 3

Preparation of Device 3-1 through 3-6.

A series of EL devices (3-1 through 3-6) were constructed in the following manner.
1. A glass substrate coated with a 25 nm layer of indium-tin oxide (ITO), as the anode, was sequentially ultrasonicated in a commercial detergent, rinsed in deionized water, degreased in toluene vapor and exposed to oxygen plasma for about 1 min.
2. Over the ITO was deposited a 1 nm fluorocarbon (CFx) hole-injecting layer (HIL) by plasma-assisted deposition of CHF₃ as described in U.S. Pat. No. 6,208,075.
3. Next a layer of hole-transporting material 4,4′-Bis[N-(1-naphthyl)-N-phenylamino]biphenyl (NPB) was deposited to a thickness of 75 nm.
4. A 20 nm light-emitting layer (LEL) corresponding to 2-phenyl-9,10-di-(2-naphthyl)-anthracene and light-emitting material, L-55 at 0.75 wt %, was then deposited.
5. An electron-transporting layer (ETL) of Inv-6 followed by Bphen with thicknesses of each as shown in Table 3, was vacuum-deposited over the LEL.
6. 0.5 nm of lithium fluoride was vacuum deposited onto the ETL, followed by a 150 nm layer of aluminum, to form a bilayer cathode cathode.

The above sequence completes the deposition of the EL device. The device is then hermetically packaged in a dry glove box for protection against ambient environment.

The devices were tested for operational voltage and luminous efficiency at an operating current of 20 mA/cm². The results are reported in Table 3 in the form of voltage (V), luminous yield (cd/A) and efficiency (w/A), where device efficiency is the radiant flux (in watts) produced by the device per amp of input current, where radiant flux is the light energy produced by the device per unit time. Light intensity is usually measured perpendicular to the device surface, and it is assumed that the angular profile is Lambertian.

TABLE 3
Evaluation results for Devices 3-1 through 3-6.

| | Inv-6 | Bphen | | Luminous | |
|---|---|---|---|---|---|
| | thickness | thickness | Voltage | Yield | Efficiency |
| Device | (nm) | (nm) | (V) | (cd/A) | (W/A) |
| 3-1 | 35.0 | 0 | 9.6 | 0.541 | 0.011 |
| 3-2 | 34.2 | 1.1 | 5.4 | 5.83 | 0.101 |
| 3-3 | 33.7 | 1.7 | 5.0 | 6.20 | 0.104 |
| 3-4 | 32.0 | 3.0 | 4.5 | 5.85 | 0.101 |
| 3-5 | 25.1 | 10.0 | 4.1 | 5.43 | 0.095 |
| 3-6 | 0 | 35.2 | 4.9 | 6.07 | 0.144 |

Varying the thicknesses of the two layers of compounds in the ETL, while keeping the total ETL thickness the same, changes the improvements in the voltage and efficiency. Using TBADN (2-(tert-butyl)-9,10-di-(2-naphthyl)-anthracene) in place of Inv-6 in Example 3-5 produced a device with a drive voltage of 5.37 V, a luminance yield of 2.98 cd/A, and an efficiency of 0.076 W/A which does not compare favorably with Example 3-5.

### Example 4

Preparation of Device 4-1 through 4-6.

Devices 4-1 through 4-6 were constructed in an identical manor as device 3-1 except Inv-9 was used in the ETL in place of Inv-6. The thickness of each material in the ETL is shown in Table 4.

The devices were tested for operational voltage and luminous efficiency at an operating current of 20 mA/cm². The results are reported in Table 4 in the form of voltage (V), luminous yield (cd/A) and efficiency (w/A), where device efficiency is the radiant flux (in watts) produced by the device per amp of input current, where radiant flux is the light energy produced by the device per unit time. Light intensity is usually measured perpendicular to the device surface, and it is assumed that the angular profile is Lambertian.

TABLE 4
Evaluation results for Devices 4-1 through 4-6.

| | Inv-9 | Bphen | | Luminous | |
|---|---|---|---|---|---|
| | thickness | thickness | Voltage | Yield | Efficiency |
| Device | (nm) | (nm) | (V) | (cd/A) | (W/A) |
| 4-1 | 35.0 | 0 | 8.8 | 0.687 | 0.015 |
| 4-2 | 33.9 | 1.0 | 5.8 | 3.41 | 0.071 |
| 4-3 | 33.8 | 1.5 | 5.1 | 4.25 | 0.087 |
| 4-4 | 31.9 | 3.0 | 4.6 | 4.98 | 0.101 |
| 4-5 | 25.2 | 10.0 | 4.1 | 5.55 | 0.107 |
| 4-6 | 0 | 35.2 | 4.8 | 6.11 | 0.149 |

Varying the thicknesses of the two layers of compounds in the ETL, while keeping the total ETL thickness the same, changes the improvements in the voltage and efficiency.

The invention has been described in detail with particular reference to certain preferred embodiments thereof, but it will be understood that variations modifications may be effected within the spirit and scope of the invention. The entire contents of the patents and other publications referred to in this specification are incorporated herein by reference.

### PARTS LIST

101 Substrate
103 Anode
105 Hole-Injecting layer (HIL)
107 Hole-Transporting layer (HTL)
109 Light-Emitting layer (LEL)
111 Electron-Transporting layer (ETL)
112 Cathode-contiguous layer
113 Cathode
150 Current/Voltage source
160 Electrical conductors

1. An OLED device comprising a cathode, an anode, and having therebetween a light emitting layer, the device further comprising a layer on the cathode side of the emitting layer containing an anthracene compound bearing a diarylamine group; provided either (1) there is present an organic layer contiguous to the cathode that is substantially free of an anthracene compound bearing a diarylamine group, or (2) there are present independently selected diarylamine groups in both the 9- and 10-positions of the anthracene.

2. An OLED device of claim 1, subparagraph (1), wherein the anthracene compound in the layer adjacent to the emitting layer is represented by Formula I: 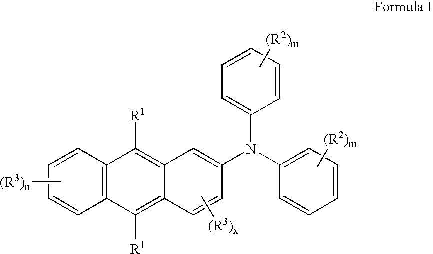
wherein;
each R¹ is independently selected from H, or a substituent selected from an aryl amine, alkyl amine, alkyl, aryl, and heteroaryl group, at least one being a substituent;
each R² and R³ is independently selected from alkyl, aryl, heteroaryl, fluoro, aryl amine, alkyl amine, and cyano groups, provided that the groups may join together to form fused rings;
each m is an integer independently selected from 0 to 5;
n is an integer independently selected from 0 to 4; and
x is an integer independently selected from 0 to 3.

3. An OLED device of claim 2, wherein;
each R¹ is selected from an alkyl, aryl, and heteroaryl group; and
each R² and R³ is independently selected from alkyl, aryl and heteroaryl groups, provided that the groups may join together to form fused rings.

4. An OLED device of claim 2, wherein; each R¹ is selected from substituted or unsubstituted phenyl, naphthyl, and anthryl groups.

5. An OLED device of claim 2, wherein the layer contiguous with the cathode comprises a compound selected from phenanthrolines, benzazoles, metal chelated oxinoids, triazines, triazoles, pyridines, oxadiazoles, and quinoxalines.

6. An OLED device of claim 1, subparagraph (1) wherein, the anthracene compound contains a diarylamine group in at least one of the 9- and 10-position and H or a substituent in the other of the 9- and 10-position; provided there is present an organic layer contiguous to the cathode that is substantially free of an anthracene compound bearing a diarylamine group in the 9- or 10-position and H or a substituent in the other of the 9- and 10-position.

7. An OLED device of claim 6, wherein the anthracene compound in the layer adjacent to the emitting layer is represented by Formula II: 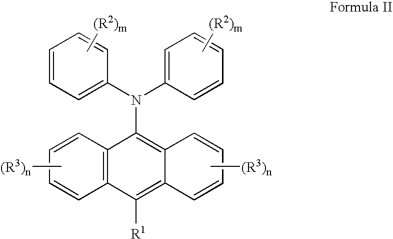
wherein;
R¹ is in the 9- or 10-position and is selected from H, aryl amine, alkyl amine, alkyl, aryl, and heteroaryl group;
each R² and R³ is independently selected from alkyl, aryl, heteroaryl, fluoro, aryl amine, alkyl amine, and cyano groups, provided that the groups may join together to form fused rings;
each m is an integer independently selected from 0 to 5; and
each n is an integer independently selected from 0 to 4.

8. An OLED device of claim 7, wherein;
R¹ is selected from an alkyl, aryl, and heteroaryl group; and
each R² and R³ is independently selected from alkyl, aryl and heteroaryl groups, provided that the groups may join together to form fused rings.

9. An OLED device of claim 7, wherein; R¹ is selected from substituted or unsubstituted phenyl, naphthyl, and anthryl groups.

10. An OLED device of claim 7, wherein; R¹ is selected from substituted or unsubstituted groups shown below:

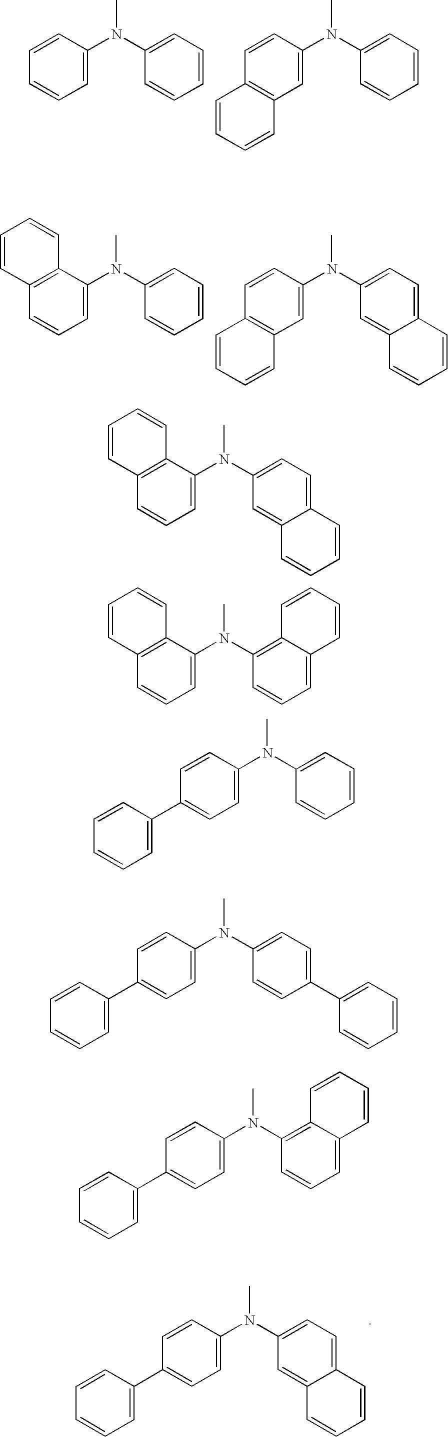

11. An OLED device of claim 7, wherein the layer contiguous to the cathode comprises a compound selected from phenanthrolines, benzazoles, metal chelated oxinoids, triazines, triazoles, pyridines, oxadiazoles, and quinoxalines.

12. An OLED device of claim 6, wherein the substituent in the other of the 9- or 10-position of the anthracene in the layer on the cathode side of the emitting layer is selected from phenyl, anthryl, naphthyl, and pentacenyl groups.

13. An OLED device of claim 1 wherein there are present independently selected diarylamine groups in both the 9- and 10-positions of the anthracene.

14. An OLED device of claim 13, wherein the anthracene compound in the layer adjacent to the emitting layer is represented by Formula III: 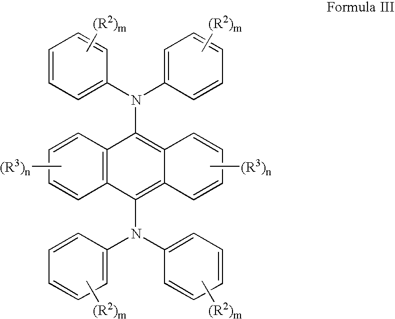
wherein;
each R² and R³ is independently selected from alkyl, aryl, heteroaryl, fluoro, aryl amine, alkyl amine, and cyano groups, provided that the groups may join together to form fused rings;
each m is an integer independently selected from 0 to 5; and
each n is an integer independently selected from 0 to 4.

15. An OLED device of claim 14, wherein the anthracene compound represented by Formula III is a 9,10-di(naphthyl phenyl amine) anthracene.

16. An OLED device of claim 15, wherein the anthracene compound in the layer adjacent to the emitting layer is represented by Formula IV: 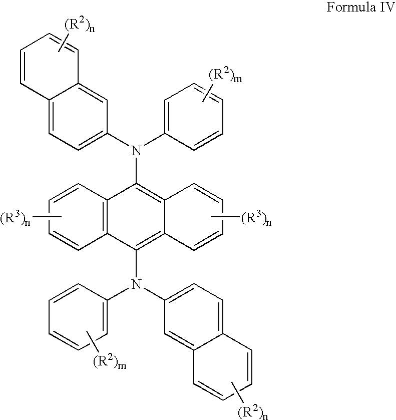
wherein;
each R² and R³ is independently selected from alkyl, aryl, heteroaryl, fluoro, aryl amine, alkyl amine, and cyano groups, provided that the groups may join together to form fused rings;
each m is an integer independently selected from 0 to 5; and
each n is an integer independently selected from 0 to 4.

17. An OLED device of claim 1 wherein the diarylamine containing anthracene is selected from the following:

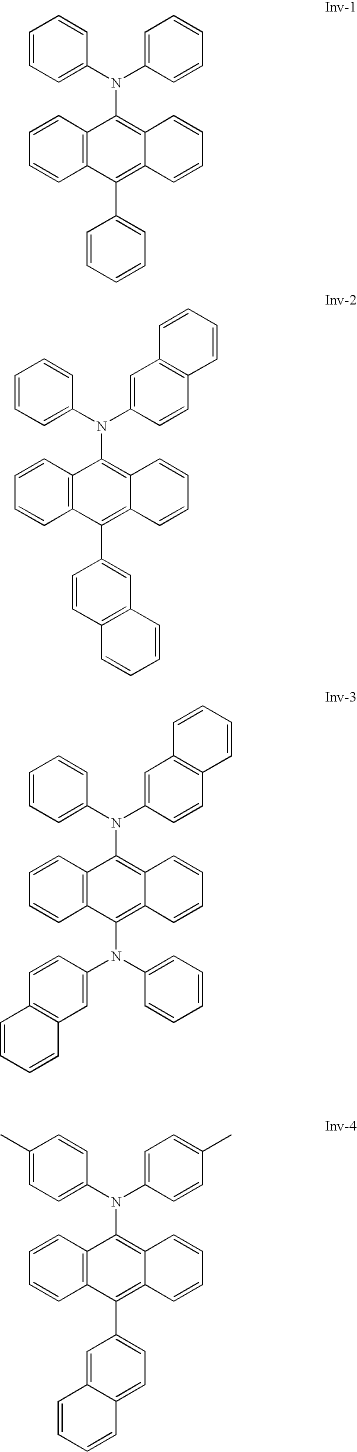

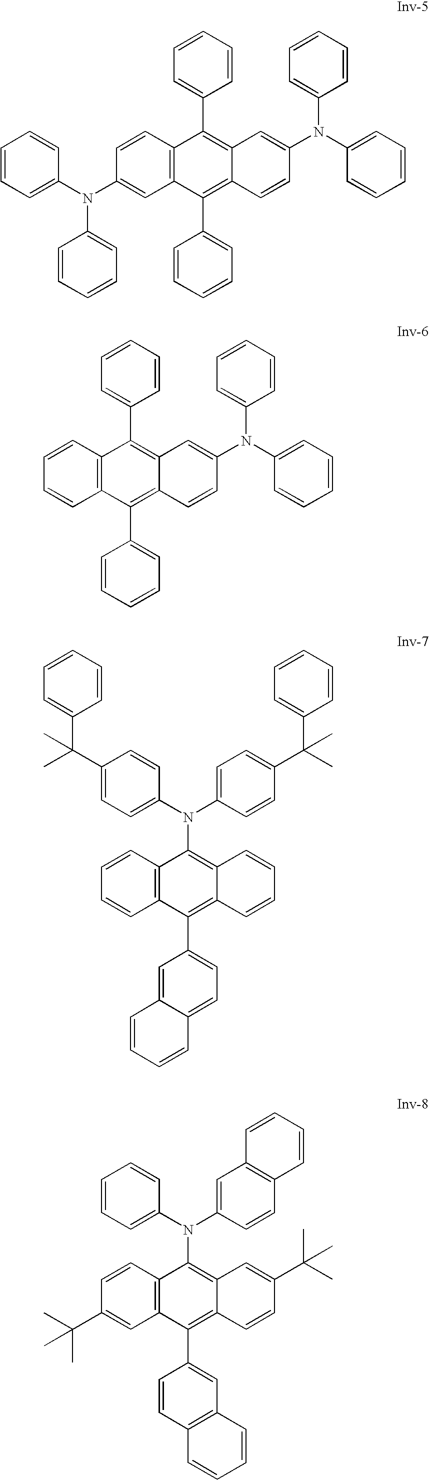

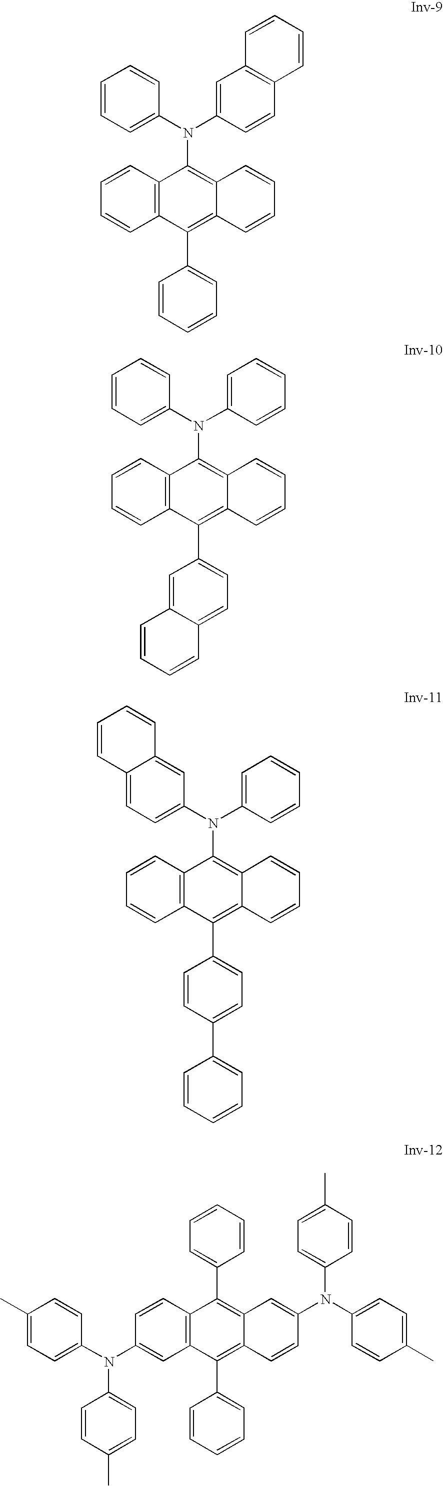

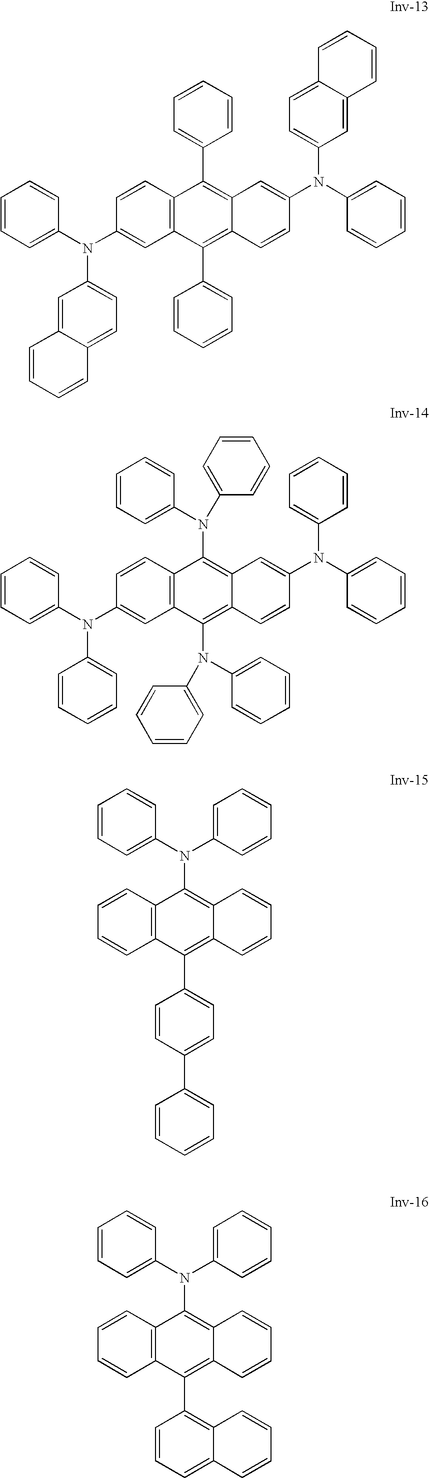

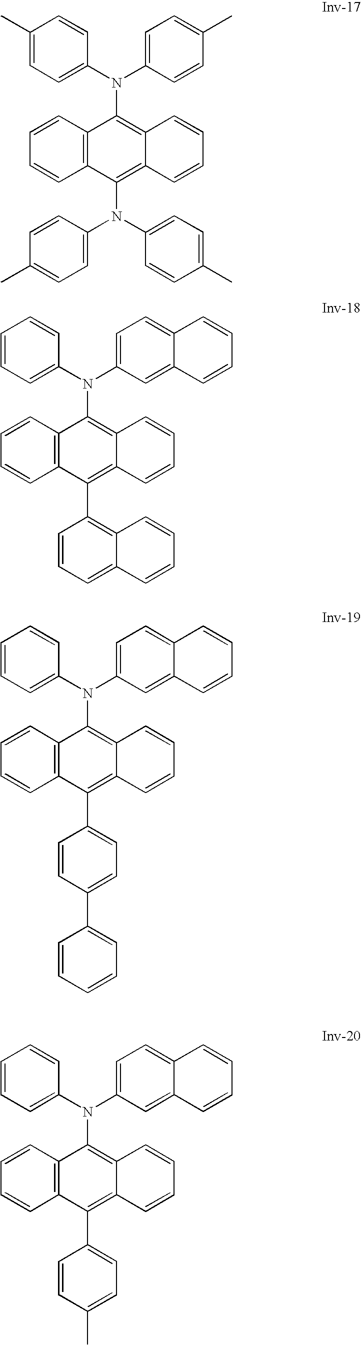

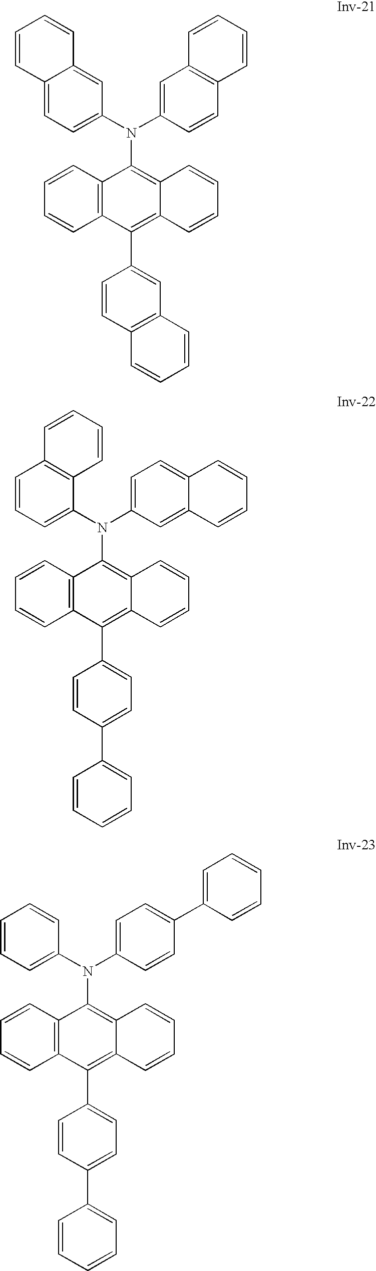

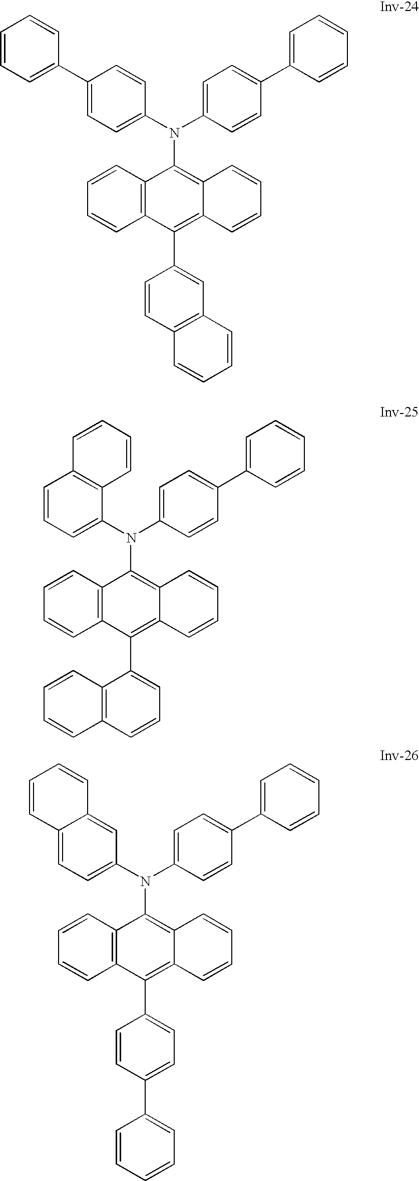

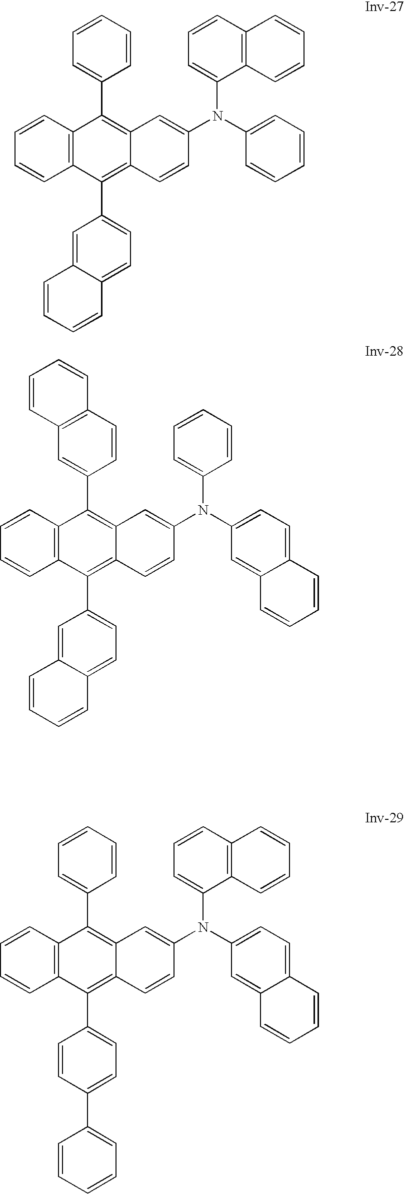

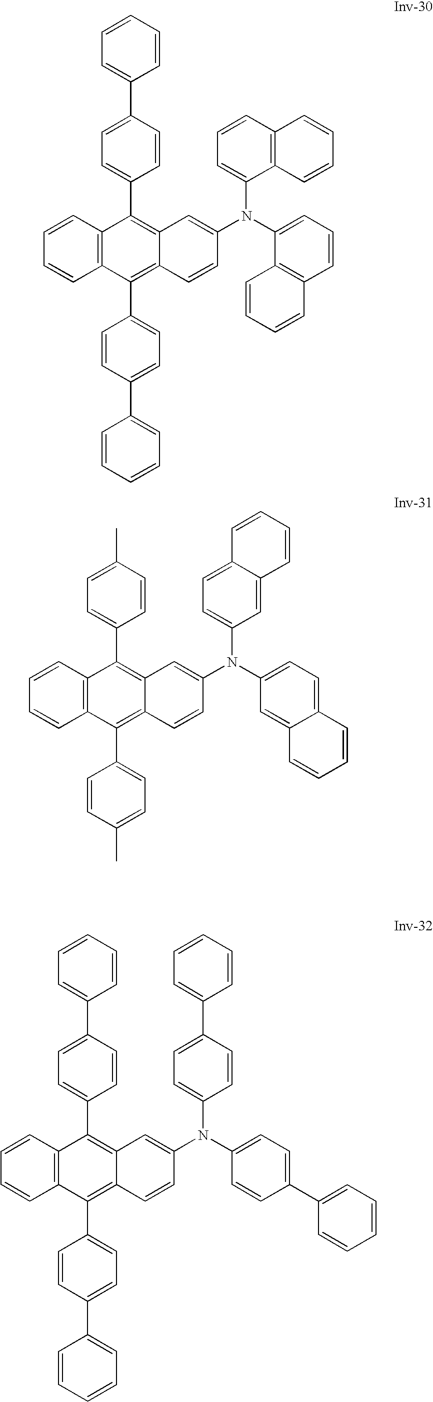

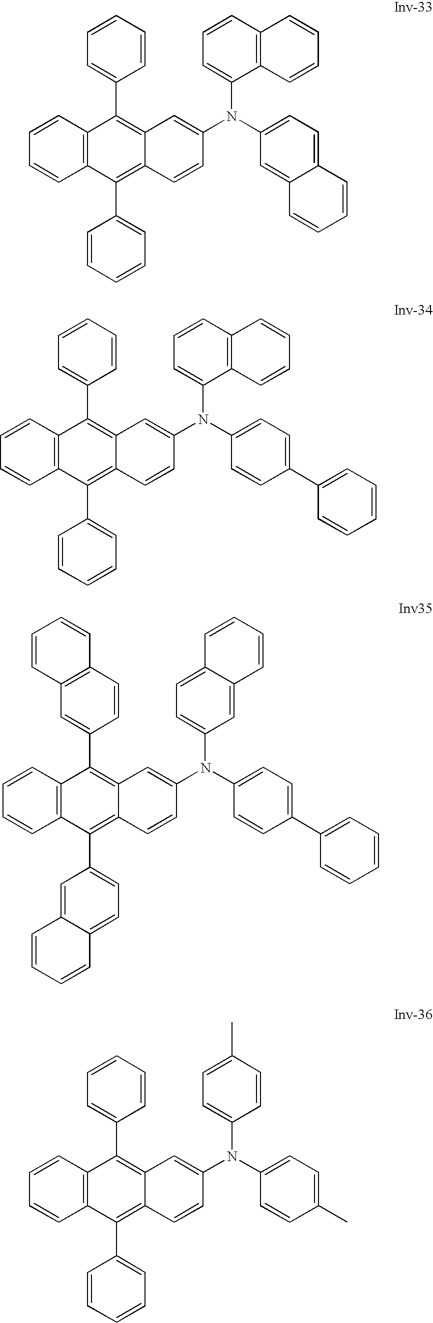

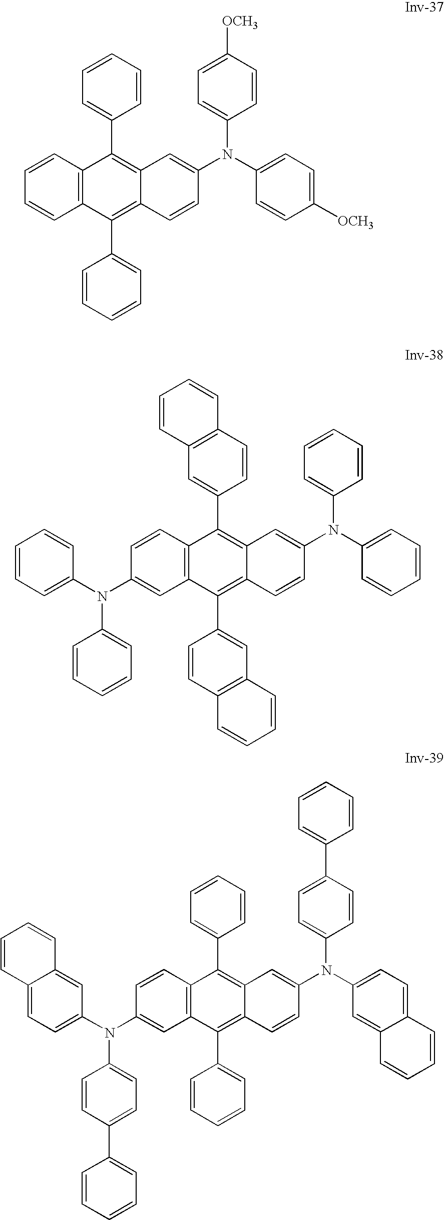

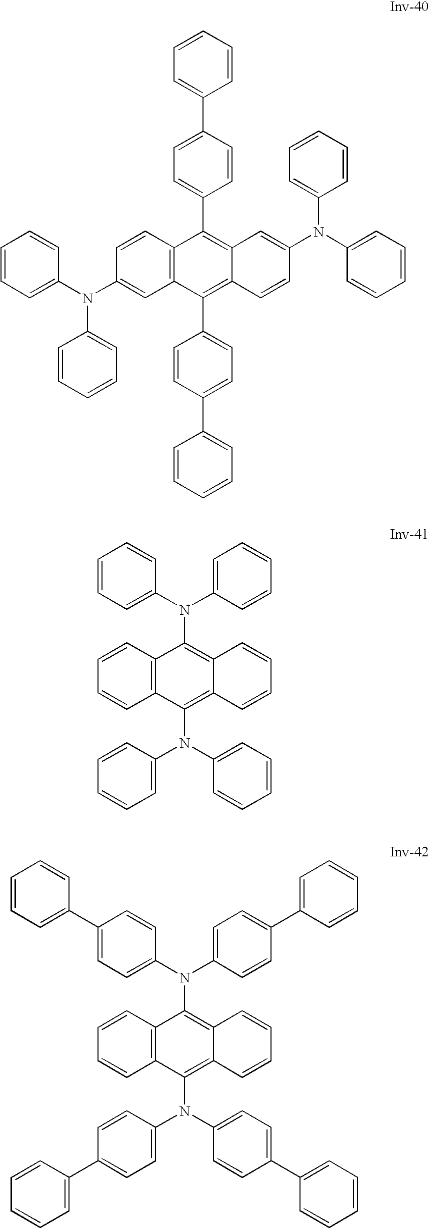

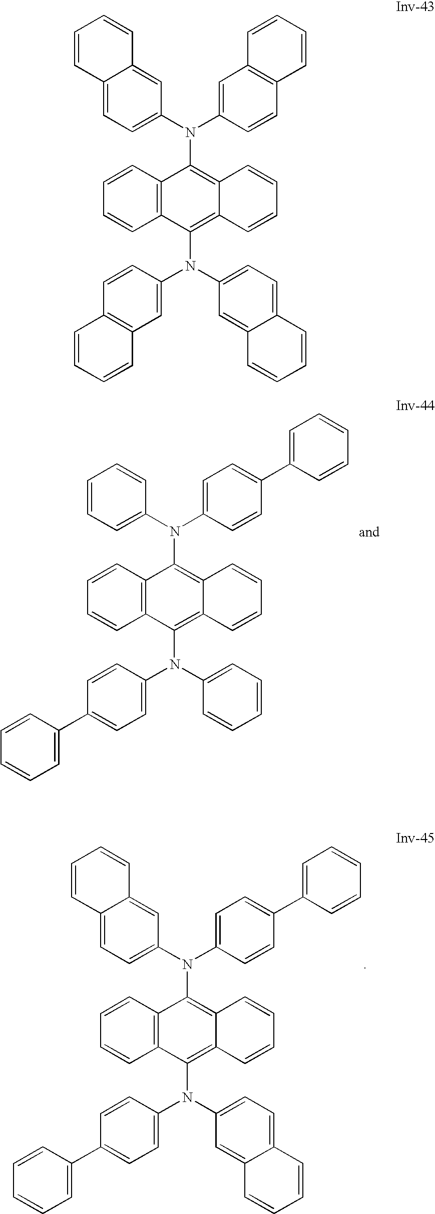

18. An OLED device of claim 1 comprising a bilayer cathode.

19. An OLED device of claim 18 wherein the bilayer cathode includes a lithium material.

20. An OLED device of claim 19 wherein the bilayer cathode includes LiF.
